(19) United States
(12) Patent Application Publication
(10) Pub. No.: US 2025/0359176 A1
(43) Pub. Date: Nov. 20, 2025

(54) FIELD EFFECT TRANSISTOR WITH ISOLATED SOURCE/DRAINS AND METHODS

(71) Applicant: Taiwan Semiconductor Manufacturing Co., Ltd., Hsinchu (TW)

(72) Inventors: Jung-Hung CHANG, Hsinchu (TW); Shih-Cheng CHEN, Hsinchu (TW); Tsung-Han CHUANG, Hsinchu (TW); Fu-Cheng CHANG, Hsinchu (TW); Wen-Ting LAN, Hsinchu (TW); Chia-Cheng TSAI, Hsinchu (TW); Kuo-Cheng CHIANG, Hsinchu (TW); Chih-Hao WANG, Hsinchu (TW); Wang-Chun HUANG, Hsinchu (TW); Shi-Syuan HUANG, Hsinchu (TW)

(73) Assignee: Taiwan Semiconductor Manufacturing Co., Ltd., Hsinchu (TW)

(21) Appl. No.: 19/288,310

(22) Filed: Aug. 1, 2025

Related U.S. Application Data
(63) Continuation of application No. 18/443,158, filed on Feb. 15, 2024.
(60) Provisional application No. 63/582,930, filed on Sep. 15, 2023.

(51) Int. Cl. H10D 30/67; H10D 30/01; H10D 30/43; H10D 62/10; H10D 62/13; H10D 64/01; H10D 84/01; H10D 84/03; H10D 84/83

(52) U.S. Cl. CPC H10D 30/6735; H10D 30/014; H10D 30/43; H10D 30/6757; H10D 62/116; H10D 62/121; H10D 62/151; H10D 64/017; H10D 64/018; H10D 84/013; H10D 84/0151; H10D 84/038; H10D 84/83

(57) ABSTRACT

A device includes: a substrate having a semiconductor fin; a stack of semiconductor channels on the substrate and positioned over the fin; a gate structure wrapping around the semiconductor channels; a source/drain abutting the semiconductor channels; an inner spacer positioned between the stack of semiconductor channels and the fin; an undoped semiconductor layer vertically adjacent the source/drain and laterally adjacent the fin; and an isolation structure that laterally surrounds the undoped semiconductor layer, the isolation structure being between the source/drain and the inner spacer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrammatic cross-sectional side views of a portion of an IC device according to embodiments of the present disclosure.

FIGS. 2A-24 are views of various embodiments of an IC device at various stages of fabrication according to various aspects of the present disclosure.

FIG. 25 is a flowchart of a method of forming an IC device in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

The present disclosure is generally related to semiconductor devices, and more particularly to field-effect transistors (FETs), such as planar FETs, three-dimensional fin FETs (FinFETs), or nanostructure FETs, such as nanosheet FETs (NSFETs), nanowire FETs (NWFETs), gate-all-around FETs (GAAFETs) and the like.

GAA logic hybrid cell devices can include different nanosheet widths to provide different effective widths (Weff). However, large nanosheet width increases cell area, whereas small nanosheet width can constrain inner spacer and source/drain epitaxy process window. Multi-sheet number selection (e.g., by disabling some nanosheets) provides different Weff for the logic hybrid cell such that cell size is reduced and process window can be increased.

Bulk substrate leakage and well isolation leakage are increasing with semiconductor scaling. A bottom isolation dielectric can be achieved by depositing a dielectric layer (e.g., SiN) between a source/drain epitaxy bottom and an undoped semiconductor to reduce effective capacitance (Ceff). However, direct current (DC) performance of a p-type FET is degraded due to p-type epitaxy strain loss.

Embodiments of the disclosure effectively isolate the source/drain epitaxy and the substrate for both n-type and p-type FETs while maintaining an improved strain effect on the pFETs. In the embodiments, a sidewall dielectric layer is positioned between a substrate/fin and an undoped semiconductor feature to isolate the source/drain epitaxy and the semiconductor feature from the surrounding substrate, while keeping the undoped semiconductor surface exposed for pFET source/drain epitaxial growth to improve strain behavior. Bulk leakage and well isolation leakage can be efficiently suppressed by the sidewall dielectrics. In some embodiments, the Ceff can be further reduced by including a bottom implant region having an anti-dopant therein. In such embodiments, the sidewall dielectric may extend adjacent to the bottommost channel(s) that are disabled.

The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure structure.

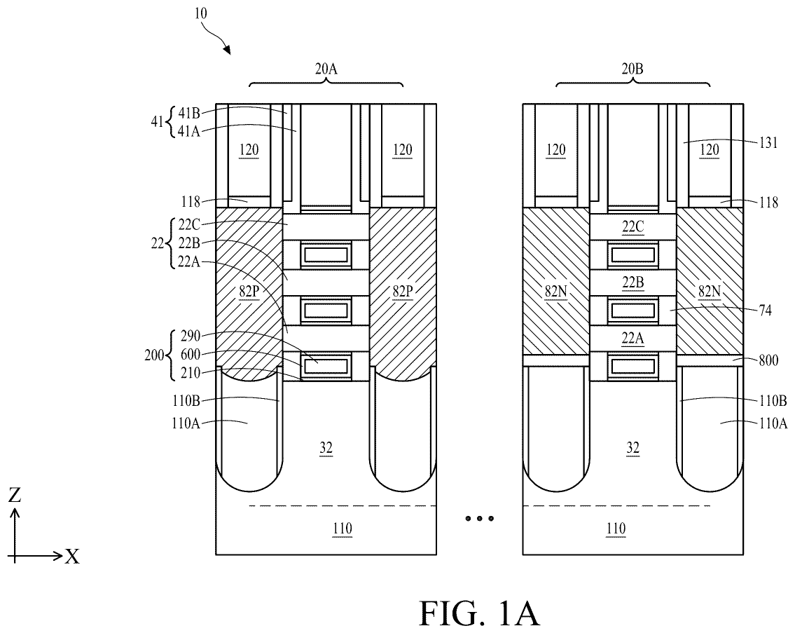

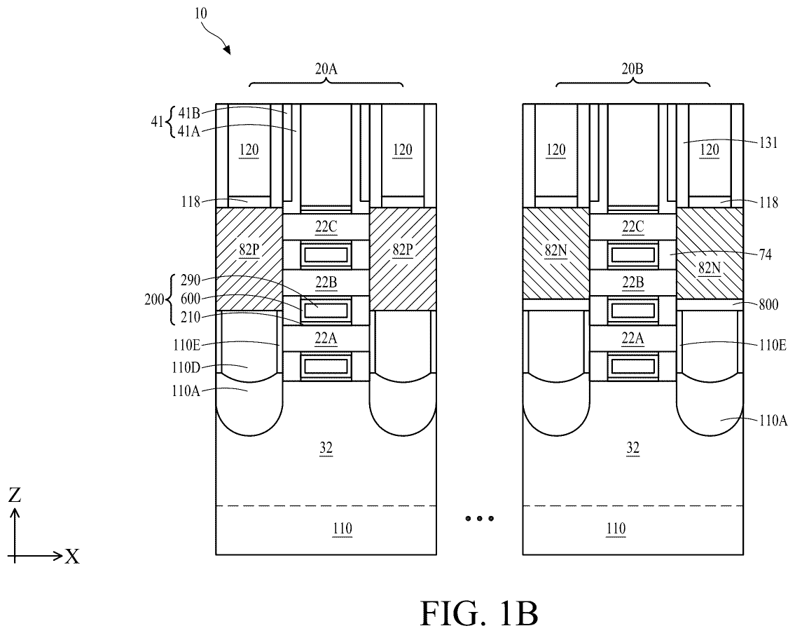

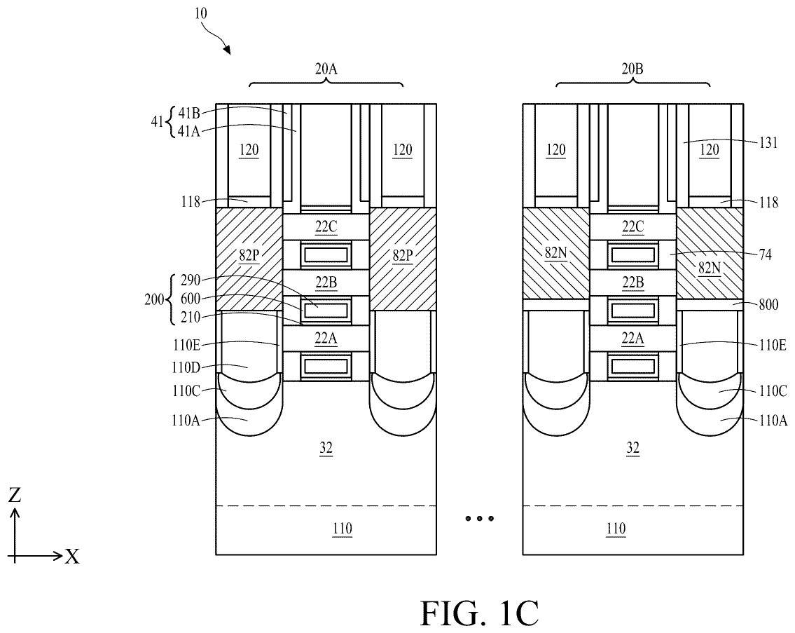

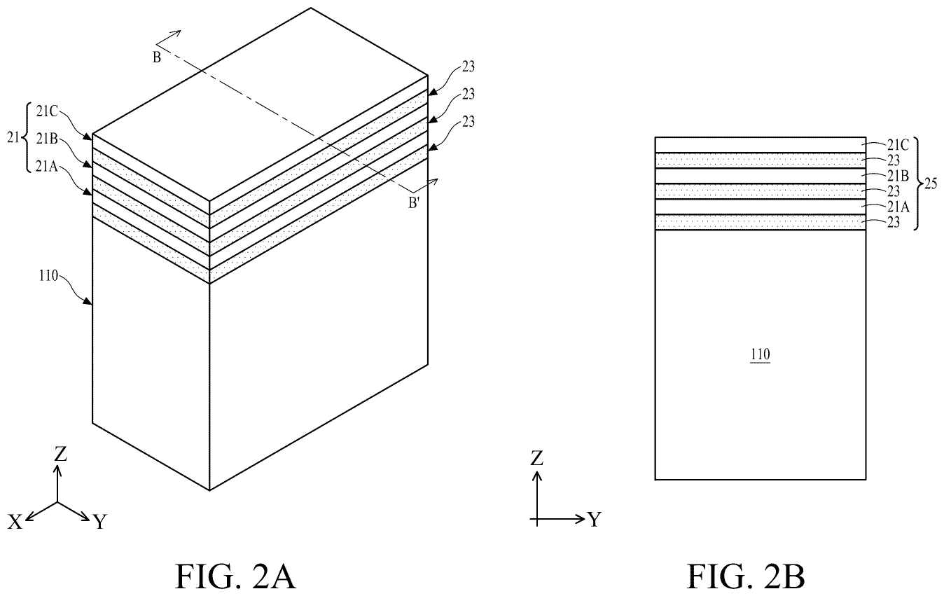

FIGS. 1A, 1B, 1C illustrate diagrammatic cross-sectional side views of a portion of a nanostructure device 10 in accordance with various embodiments. Description is provided with reference to FIG. 1A, which illustrates a view in an X-Z plane, in which isolation structures 110B that isolate respective semiconductor features 110A from a substrate 110 or fin 32 are positioned beneath source/drain regions 82P, 82N. The nanostructure device 10 of FIG. 1A is described in detail below to provide context for understanding the technical features and benefits of the various embodiments depicted in FIGS. 2A-24. Source/drain region(s) may refer to a source or a drain, individually or collectively dependent upon the context.

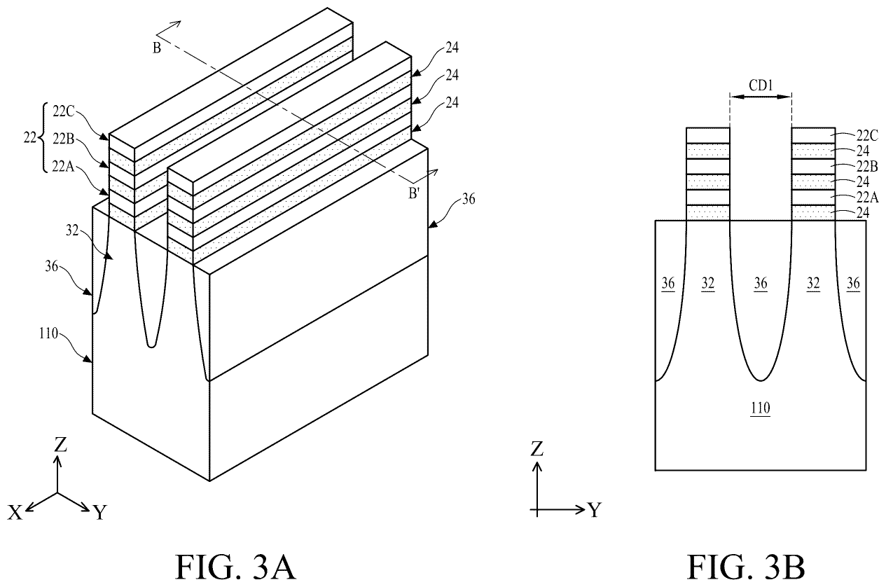

Referring to FIG. 1A, nanostructure devices 20A, 20B may be or include one or more N-type FETs (NFETs) or P-type FETs (PFETs). The nanostructure devices 20A, 20B are formed over and/or in a substrate 110, and generally include gate structures 200 straddling and/or wrapping around semiconductor channels 22A, 22B, 22C (or “channels 22”), alternatively referred to as “nanostructures,” located over semiconductor fins 32 protruding from, and separated by, isolation structures 36 (see FIG. 3B). The gate structure 200 controls electrical current flow through the channels 22A, 22B, 22C.

The nanostructure devices 20A, 20B are shown including three channels 22A, 22B, 22C, which are laterally abutted by source/drain features 82N, 82P, and covered and surrounded by the gate structure 200. Generally, the number of channels 22 is two or more, such as three or four or more. The gate structure 200 controls flow of electrical current through the channels 22A, 22B, 22C to and from the source/drain features 82N, 82P based on voltages applied at the gate structure 200 and at the source/drain features 82N, 82P.

In some embodiments, the fin structure 32 includes silicon. In some embodiments, the nanostructure device 20B includes an NFET, and the source/drain features 82N thereof include silicon phosphorous (SiP), SiAs, SiSb, SiPAs, SiP:As:Sb, combinations thereof, or the like. In some embodiments, the nanostructure device 20A includes a PFET, and the source/drain features 82P thereof include silicon germanium (SiGe), either undoped or doped to form, for example, SiGe:B, SiGe:B:Ga, SiGe:Sn, SiGe:B:Sn, or another appropriate semiconductor material. Generally, the source/drain features 82N, 82P may include any combination of appropriate semiconductor material(s) and appropriate dopant(s). In the embodiment depicted in FIG. 1A, the nanostructure device 20A includes a PFET and the nanostructure device 20B includes an NFET.

The channels 22A, 22B, 22C each include a semiconductive material, for example silicon or a silicon compound, such as silicon germanium, or the like. The channels 22A, 22B, 22C are nanostructures (e.g., having sizes that are in a range of a few nanometers) and may also each have an elongated shape and extend in the X-direction. In some embodiments, the channels 22A, 22B, 22C each have a nanowire (NW) shape, a nanosheet (NS) shape, a nanotube (NT) shape, or other suitable nanoscale shape. The cross-sectional profile of the channels 22A, 22B, 22C may be rectangular, round, square, circular, elliptical, hexagonal, or combinations thereof.

In some embodiments, the lengths (e.g., measured in the X-direction) of the channels 22A, 22B, 22C may be different from each other, for example due to tapering during a fin etching process (see FIGS. 3A, 3B). In some embodiments, length of the channel 22C may be less than a length of the channel 22B, which may be less than a length of channel 22A. The channels 22A, 22B, 22C each may not have uniform thickness (e.g., along the X-axis direction), for example due to a channel trimming process used to expand spacing (e.g., measured in the Z-axis direction) between the channels 22A, 22B, 22C to increase gate structure fabrication process window. For example, a middle portion of each of the channels 22A, 22B, 22C may be thinner than the two ends of each of the channels 22A, 22B, 22C. Such shape may be collectively referred to as a “dog-bone” shape.

In some embodiments, the spacing between the channels 22A, 22B, 22C (e.g., between the channel 22B and the channel 22A or the channel 22C) is in a range between about 8 nanometers (nm) and about 12 nm, though ranges exceeding or below the said range may also be beneficial. In some embodiments, a thickness (e.g., measured in the Z-direction) of each of the channels 22A, 22B, 22C is in a range between about 5 nm and about 8 nm, though ranges exceeding or below the said range may also be beneficial. In some embodiments, a width (e.g., measured in the Y-direction, orthogonal to the X-Z plane) of each of the channels 22A, 22B, 22C is at least about 8 nm, however the width may be less than 8 nm in some embodiments.

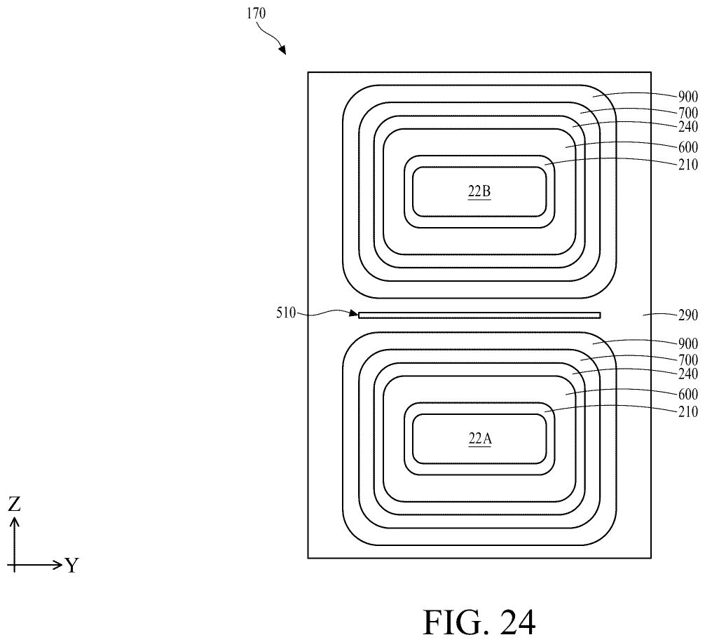

The gate structure 200 is disposed over and between the channels 22A, 22B, 22C, respectively. In some embodiments, the gate structure 200 is disposed over and between the channels 22A, 22B, 22C, which are silicon channels for N-type devices or silicon germanium channels for P-type devices. In some embodiments, the gate structure 200 includes an interfacial layer (IL) 210, one or more gate dielectric layers 600 on the interfacial layer 210, optionally one or more work function tuning layers 900 (see FIG. 24) on the gate dielectric layer 600 and a metal core layer 290 on the gate dielectric layer 600 and optionally on the work function tuning layer 900.

The interfacial layer 210, which may be an oxide of the material of the channels 22A, 22B, 22C, is formed on exposed areas of the channels 22A, 22B, 22C and the top surface of the fin 32. The interfacial layer 210 promotes adhesion of the gate dielectric layers 600 to the channels 22A, 22B, 22C. In some embodiments, the interfacial layer 210 has thickness of about 5 Angstroms (A) to about 50 Angstroms (A). In some embodiments, the interfacial layer 210 has thickness of about 10 A. The interfacial layer 210 having thickness that is too thin may exhibit voids or insufficient adhesion properties. The interfacial layer 210 being too thick consumes gate fill window, which is related to threshold voltage tuning and resistance. In some embodiments, the interfacial layer 210 is doped with a dipole, such as lanthanum, for threshold voltage tuning.

In some embodiments, the gate dielectric layer 600 includes at least one high-k gate dielectric material, which may refer to dielectric materials having a high dielectric constant that is greater than a dielectric constant of silicon oxide (k≈3.9). Example high-k dielectric materials include HfO₂, HfSiO, HfSiON, HfTaO, HfTiO, HfZrO, ZrO₂, Ta₂O₅, or combinations thereof. In some embodiments, the gate dielectric layer 600 has thickness of about 5 A to about 100 A. The gate dielectric layer 600 may be a single layer or a multilayer.

The gate structure 200 also includes metal core layer 290. The metal core layer 290 may include a conductive material such as Co, W, Ru, combinations thereof, or the like. In some embodiments, the metal core layer 290 is or includes a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. Between the channels 22A, 22B, 22C, the metal core layer 290 is circumferentially surrounded (in the cross-sectional view) by the one or more work function metal layers 900, which are then circumferentially surrounded by the gate dielectric layers 600, which are circumferentially surrounded by the interfacial layer 210. The gate structure 200 may also include a glue layer that is formed between the one or more work function layers 900 and the metal core layer 290 to increase adhesion. The glue layer is not specifically illustrated in FIG. 1A for simplicity.

The nanostructure devices 20A, 20B may further include source/drain contacts 120 that are formed over the source/drain features 82N, 82P. The source/drain contacts 120 may include a core layer that is or includes a conductive material such as tungsten, ruthenium, cobalt, copper, titanium, titanium nitride, tantalum, tantalum nitride, iridium, molybdenum, nickel, aluminum, or combinations thereof. The core layer may be surrounded by one or more liner (or, “barrier”) layers, such as SiN or TiN, which help prevent or reduce diffusion of materials from and into the source/drain contacts 120. In some embodiments, height of the source/drain contacts 120 may be in a range of about 1 nm to about 50 nm.

Silicide layers 118 are positioned between the source/drain features 82N, 82P and the source/drain contacts 120, at least to reduce the source/drain contact resistance. In some embodiments, the silicide layer 118 is or includes TiSi, CrSi, TaSi, MoSi, ZrSi, HfSi, ScSi, YSi, HoSi, TbSi, GdSi, LuSi, DySi, ErSi, YbSi, or the like. In some embodiments, the silicide layer 118 is or includes NiSi, CoSi, MnSi, WSi, FeSi, RhSi, PdSi, RuSi, PtSi, IrSi, OsSi, or the like. The silicide layer 118 may have thickness in a range of about 1 nm to about 10 nm. Thickness lower than about 1 nm may lead to an insufficient reduction in contact resistance. Thickness above about 10 nm may cause electrical shorting with the nanostructures 22. In some embodiments, the silicide layer 118 is present below, and in contact with, etch stop layer 131.

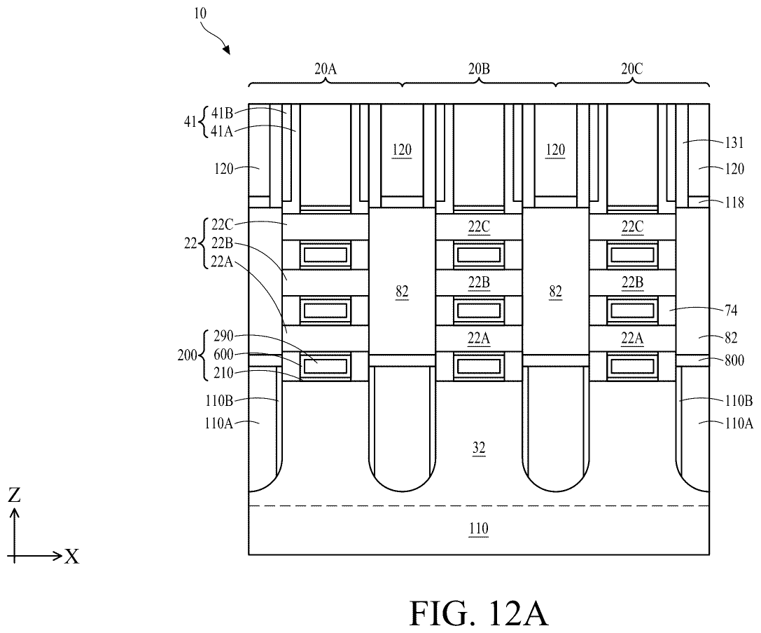

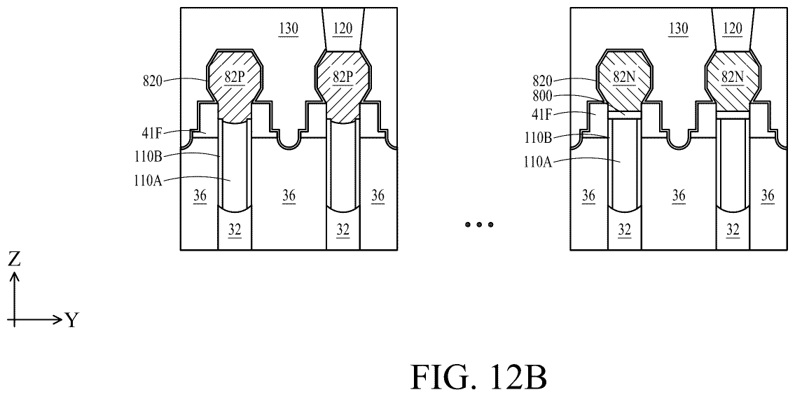

The nanostructure devices 20A, 20B may further include an interlayer dielectric (ILD) 130, which is depicted in FIG. 12B. The ILD 130 provides electrical isolation between the various components of the nanostructure devices 20A, 20B discussed above, for example between neighboring pairs of the source/drain contacts 120. An etch stop layer 131 may be formed prior to forming the ILD 130 and may be positioned laterally between the ILD 130 and the gate spacers 41 and vertically between the ILD 130 and the source/drain features 82N, 82P. In some embodiments, the etch stop layer 131 is or includes SiN, SiCN, SiC, SiOC, SiOCN, HfO2, ZrO2, ZrAlOx, HfAlOx, HfSiOx, Al2O3, or other suitable material. In some embodiments, thickness of the etch stop layer is in a range of about 1 nm to about 5 nm. In some embodiments, where the ILD 130 is not present (e.g., is removed completely prior to formation of the source/drain contacts 120), the etch stop layer 131 may be in contact with the source/drain contact 120. The etch stop layer 131 may be trimmed, for example, in the X-axis direction prior to formation of the source/drain contact 120 to improve fill quality of the source/drain contact 120.

The nanostructure devices 20A, 20B include gate spacers 41 that are disposed on sidewalls of the metal core layer 290, the gate dielectric layer 600 and the IL 210 above the channel 22A, and inner spacers 74 that are disposed on sidewalls of the IL 210 and/or the gate dielectric layer 600 between the channels 22A, 22B, 22C. The inner spacers 74 are also disposed between the channels 22A, 22B, 22C. In the embodiment depicted in FIG. 1A, the gate spacers 41 include a first spacer layer 41A and a second spacer layer 41B on the first spacer layer 41A. The first and second spacer layers 41A, 41B may each include a dielectric material, for example a low-k material such as SiOCN, SiON, SiN, SiCN, SiOC or the like. In some embodiments, the second spacer layer 41B is not present. Material of the first and second spacer layers 41A, 41B may be the same as or different from each other. In some embodiments, an upper portion of the second spacer layer 41B (or the first spacer layer 41A when the second spacer layer 41B is not present) may be removed partially or fully to increase aspect ratio of an opening through which the source/drain region 82N, 82P is formed. FIG. 1A depicts an embodiment in which the upper portion of the second spacer layer 41B is not thinned.

The isolation features 110B extend from a lower surface of the source/drains 82 to a level that is below the upper surface of the fin 32. In some embodiments, the semiconductor features 110A are undoped semiconductor, such as silicon, silicon germanium or the like, that is grown in a source/drain opening(s). The semiconductor features 110A can provide an improved surface for growing the source/drains 82P. In devices including a bottom insulator or bottom isolation layer 800, such as the nanostructure device 20B, the semiconductor feature 110A may provide a flat surface that is at about a level of a lowermost inner spacer 74, which can be beneficial for positioning the bottom insulator 800 near a level of the bottommost channel 22A. The isolation features 110B provide electrical isolation between the source/drains 82N, 82P and the underlying substrate 110 and/or fin 32, which can reduce leakage current from the source/drains 82N, 82P into the substrate 110 and/or fin 32. The isolation features 110B may be vertical thin dielectric layers that are between sidewalls of each respective fin 32 and semiconductor feature 110A. In some embodiments, the isolation features 110B are in direct contact with the sidewalls of the fin 32 and the semiconductor feature 110A. In some embodiments, the isolation features 110B are or include a dielectric material, such as one or more of SiOC, SiOCN, SiCN, SiN, combinations thereof and the like.

FIG. 1B depicts an embodiment in which one or more of the channels 22 is disabled, which decreases Weff of the nanostructure devices 20A, 20B. The device 10 depicted in FIG. 1B is similar in many respects to the device 10 described with reference to FIG. 1A and like reference numerals refer to like elements. In FIG. 1B, the nanostructure devices 20A, 20B include channel isolation structures 110D and channel isolation layers 110E that extend from about a level of an upper surface of the fin 32 to a level above one or more channels 22 of the nanostructure devices 20A, 20B. For example, as depicted in FIG. 1B, the channel isolation structures 110D and channel isolation layers 110E extend to a level above the bottommost channel 22A, such that the channels 22B, 22C are active and can conduct electrical current, whereas the bottommost channel 22A is inactive/disabled and may not conduct electrical current.

FIG. 1C depicts an embodiment in which one or more of the channels 22 is disabled, which decreases Weff of the nanostructure devices 20A, 20B. The device 10 depicted in FIG. 1C is similar in many respects to the devices 10 described with reference to FIG. 1B and FIG. 1C and like reference numerals refer to like elements. In addition to or instead of the channel isolation structures 110D and channel isolation layers 110E, as depicted in FIG. 1C, the nanostructure devices 20A, 20B include implantation regions 110C that can increase electrical isolation to the substrate 110 and/or fin 32. The implantation regions 110C can include anti-dopants, which can be dopants that are an opposite type from that of the overlying source/drain 82N, 82P. For example, the source/drain 82N may include dopant ions of P, As, Sb, Bi or the like, and the implantation region 110C underneath the source/drain region 82N may include dopant ions of B, Al, Ga, In, Zn or the like. In another example, the source/drain 82P include dopant ions of B, Al, Ga, In, Zn or the like, and the implantation region 110C underneath the source/drain region 82N may include dopant ions of P, As, Sb, Bi or the like.

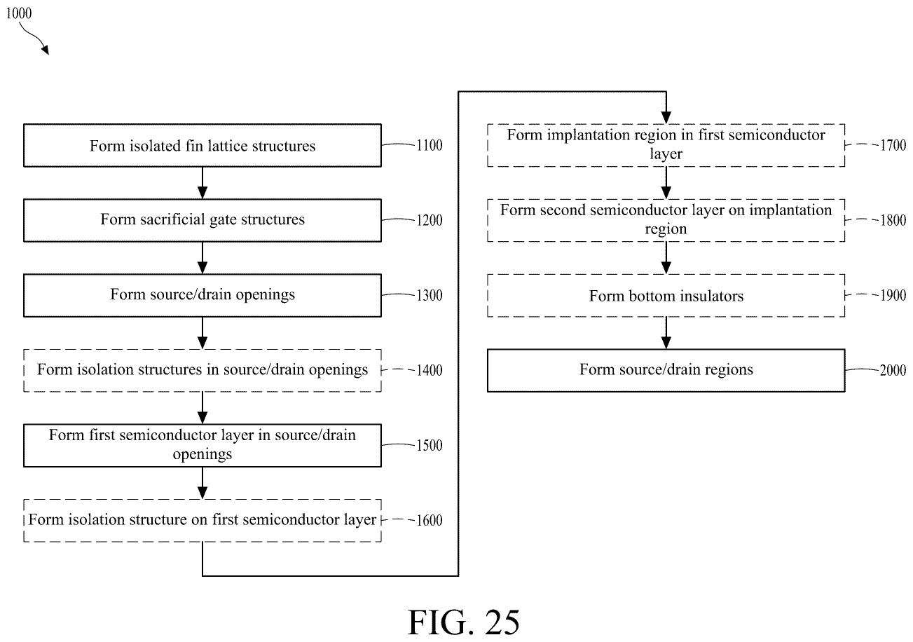

FIG. 25 depicts a flowchart of a method 1000 for forming an IC device or a portion thereof from a workpiece, according to one or more aspects of the present disclosure. Method 1000 is merely an example and not intended to limit the present disclosure to what is explicitly illustrated in method 1000. Additional acts can be provided before, during and after the method 1000 and some acts described can be replaced, eliminated, or moved around for additional embodiments of the method. Not all acts are described herein in detail for reasons of simplicity. Method 1000 is described below in conjunction with fragmentary perspective and/or cross-sectional views of a workpiece, shown in FIGS. 2A-24, at different stages of fabrication according to embodiments of method 1000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

FIGS. 2A through 24 are views of intermediate stages in the manufacturing of FETs, such as nanostructure FETs, in accordance with some embodiments.

In FIG. 2A and FIG. 2B, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 2A and FIG. 2B, a multi-layer stack 25 or “lattice” is formed over the substrate 110 of alternating layers of first semiconductor layers 21A, 21B, 21C (collectively referred to as first semiconductor layers 21) and second semiconductor layers 23. In some embodiments, the first semiconductor layers 21 may be formed of a first semiconductor material suitable for n-type nano-FETs, such as silicon, silicon carbide, or the like, and the second semiconductor layers 23 may be formed of a second semiconductor material suitable for p-type nano-FETs, such as silicon germanium or the like. Each of the layers 21, 23 of the multi-layer stack 25 may be epitaxially grown using a process such as chemical vapor deposition (CVD), atomic layer deposition (ALD), vapor phase epitaxy (VPE), molecular beam epitaxy (MBE), or the like.

Three layers of each of the first semiconductor layers 21 and the second semiconductor layers 23 are illustrated. In some embodiments, the multi-layer stack 25 may include fewer or additional pairs of the first semiconductor layers 21 and the second semiconductor layers 23. Although the multi-layer stack 25 is illustrated as including a second semiconductor layer 23 as the bottommost layer, in some embodiments, the bottommost layer of the multi-layer stack 25 may be a first semiconductor layer 21.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions of nano-FETs. In some embodiments, the first semiconductor layers 21 are removed and the second semiconductor layers 23 are patterned to form channel regions. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions of nano-FETs.

In FIG. 3A and FIG. 3B, fins 32 are formed in the substrate 110 and nanostructures 22, 24 are formed in the multi-layer stack 25 corresponding to act 1100 of FIG. 25. In some embodiments, the nanostructures 22, 24 and the fins 32 may be formed by etching trenches in the multi-layer stack 25 and the substrate 110. The etching may be any acceptable etch process, such as a reactive ion etch (RIE), neutral beam etch (NBE), the like, or a combination thereof. The etching may be anisotropic. First nanostructures 22A, 22B, 22C (also referred to as “channels 22” below) are formed from the first semiconductor layers 21, and second nanostructures 24 are formed from the second semiconductor layers 23. Distance CD1 between adjacent fins 32 and nanostructures 22, 24 may be from about 18 nm to about 100 nm. A portion of the device 10 is illustrated in FIGS. 3A and 3B including two fins 32 for simplicity of illustration. The process 1000 illustrated in FIG. 25 may be extended to any number of fins, and are not limited to the two fins 32 shown in FIGS. 3A-24.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

FIGS. 3A and 3B illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIGS. 3A and 3B, isolation regions or features 36, which may be shallow trench isolation (STI) regions or features, are formed adjacent the fins 32. The isolation regions 36 may be formed by depositing an insulation material over the substrate 110, the fins 32, and nanostructures 22, 24, and between adjacent fins 32 and nanostructures 22, 24. The insulation material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, and the nanostructures 22, 24. Thereafter, a core material, such as those discussed above may be formed over the liner.

The insulation material undergoes a removal process, such as a chemical mechanical polish (CMP), an etch-back process, combinations thereof, or the like, to remove excess insulation material over the nanostructures 22, 24. Top surfaces of the nanostructures 22, 24 may be exposed and level with the insulation material after the removal process is complete.

The insulation material is then recessed to form the isolation regions 36. After recessing, the nanostructures 22, 24 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHF), which is selective to the insulation material and leaves the fins 32 and the nanostructures 22, 24 substantially unaltered.

FIGS. 2A through 3B illustrate one embodiment (e.g., etch last) of forming the fins 32 and the nanostructures 22, 24. In some embodiments, the fins 32 and/or the nanostructures 22, 24 are epitaxially grown in trenches in a dielectric layer (e.g., etch first). The epitaxial structures may comprise the alternating semiconductor materials discussed above, such as the first semiconductor materials and the second semiconductor materials.

In FIG. 3A and FIG. 3B, appropriate wells (not separately illustrated) may be formed in the fins 32, the nanostructures 22, 24, and/or the isolation regions 36. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities. In some embodiments, in situ doping during epitaxial growth of the fins 32 and the nanostructures 22, 24 may obviate separate implantations, although in situ and implantation doping may be used together.

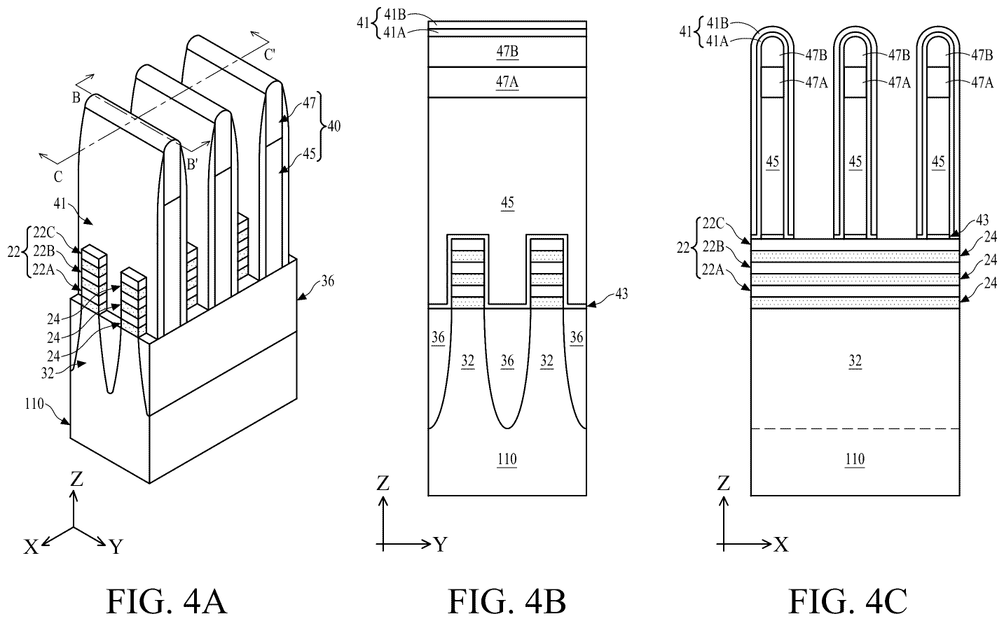

In FIGS. 4A-4C, dummy or sacrificial gate structures 40 are formed over the fins 32 and/or the nanostructures 22, 24, corresponding to act 1200 of FIG. 25. A dummy or sacrificial gate layer 45 is formed over the fins 32 and/or the nanostructures 22, 24. The dummy gate layer 45 may be or include materials that have a high etching selectivity relative to the isolation regions 36. The dummy gate layer 45 may be a conductive, semiconductive or non-conductive material and may be or include amorphous silicon, polycrystalline-silicon (polysilicon), polycrystalline silicon-germanium (poly-SiGe), metallic nitrides, metallic silicides, metallic oxides, and metals. The dummy gate layer 45 may be deposited by physical vapor deposition (PVD), CVD, sputter deposition, or other techniques for depositing the selected material. A mask layer 47 is formed over the dummy gate layer 45, and may include, for example, silicon nitride, silicon oxynitride, or the like. In some embodiments, a gate dielectric layer 43 is formed before the dummy gate layer 45 between the dummy gate layer 45 and the fins 32 and/or the nanostructures 22, 24. In some embodiments, the mask layer 47 includes a first mask layer 47A in contact with the dummy gate layer 45, and a second mask layer 47B overlying and in contact with the first mask layer 47A. The first mask layer 47A may be or include the same or different material as that of the second mask layer 47B.

A spacer layer 41 is formed over sidewalls of the mask layer 47 and the dummy gate layer 45. The spacer layer 41 is or includes an insulating material, such as SiOCN, SiOC, SiCN or the like (or any of the materials described with reference to FIG. 1A) and may have a single-layer structure or a multi-layer structure including a plurality of dielectric layers, in accordance with some embodiments. The spacer layer 41 may be formed by depositing a spacer material layer (not shown) over the mask layer 47 and the dummy gate layer 45. Portions of the spacer material layer between dummy gate structures 40 are removed using an anisotropic etching process, in accordance with some embodiments. In some embodiments, as shown in detail in FIGS. 4B, 4C, the spacer layer 41 includes a first spacer layer 41A in contact with the nanostructure 22C, the gate dielectric layer 43, the dummy gate layer 45 and the first and second mask layers 47A, 47B. A second spacer layer 41B of the spacer layer 41 may be in contact with the first spacer layer 41A. The first spacer layer 41A may be or include the same or different material as that of the second spacer layer 41B.

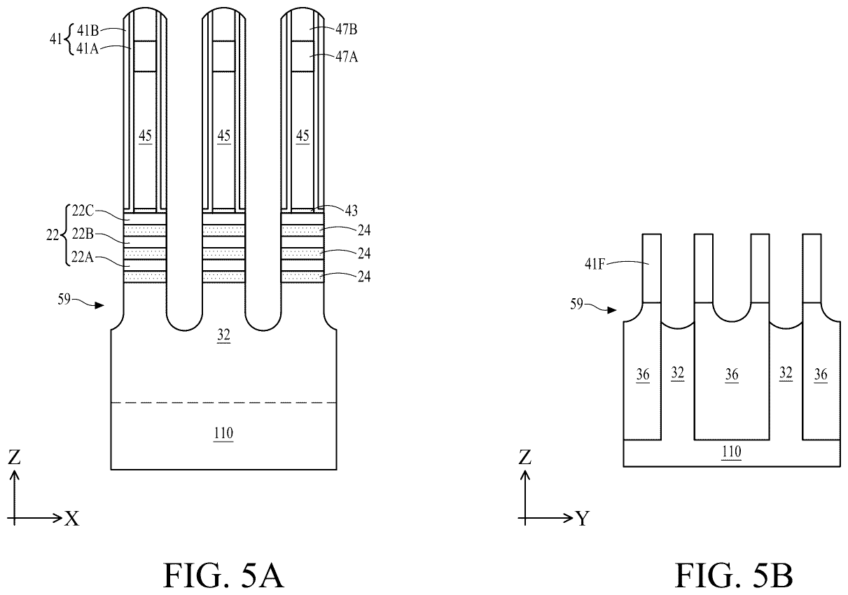

In FIGS. 5A and 5B, source/drain openings 59 are formed by performing an etching process to etch the portions of protruding fins 32 and/or nanostructures 22, 24 that are not covered by dummy gate structures 40, corresponding to act 1300 of FIG. 25. The recessing may be anisotropic, such that the portions of fins 32 directly underlying dummy gate structures 40 and the spacer layer 41 are protected and are not substantially etched. The top surfaces of the recessed fins 32 may be substantially coplanar with the top surfaces of the isolation regions 36, in accordance with some embodiments. The top surfaces of the recessed fins 32 may be lower than the top surfaces of the isolation regions 36, in accordance with some other embodiments, as depicted in FIG. 5B. FIG. 5A depicts three vertical stacks of nanostructures 22, 24 following the etching process for simplicity. In general, the etching process may be used to form fewer or additional vertical stacks of nanostructures 22, 24 over the fins 32 than those depicted. In some embodiments, the second mask layer 47B is exposed following the etching process, for example, due to removal of upper portions of the spacer layers 41A, 41B during the etching process. FIG. 5B depicts fin spacers 41F which are portions of the first and/or second spacer layers 41A, 41B that overlie the isolation regions 36 adjacent to respective fins 32.

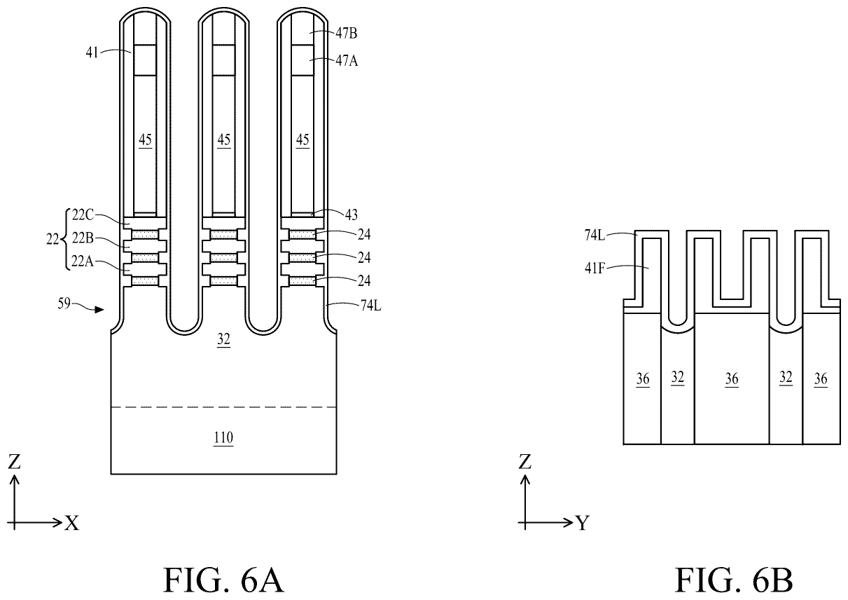

FIGS. 6A-10B depict formation of inner spacers and isolation structures 110B in the source/drain openings 59.

In FIGS. 6A, 6B, a selective etching process is performed to recess end portions of the nanostructures 24 exposed by openings in the spacer layer 41 without substantially attacking the nanostructures 22. After the selective etching process, recesses are formed in the nanostructures 24 at locations where the removed end portions used to be. Then, following formation of the recesses, an inner spacer layer 74L is formed to fill (partially or entirely) the recesses in the nanostructures 22 formed by the previous selective etching process. The inner spacer layer 74L may be a suitable dielectric material, such as silicon carbon nitride (SiCN), silicon oxycarbonitride (SiOCN), or the like, formed by a suitable deposition method such as PVD, CVD, ALD, or the like.

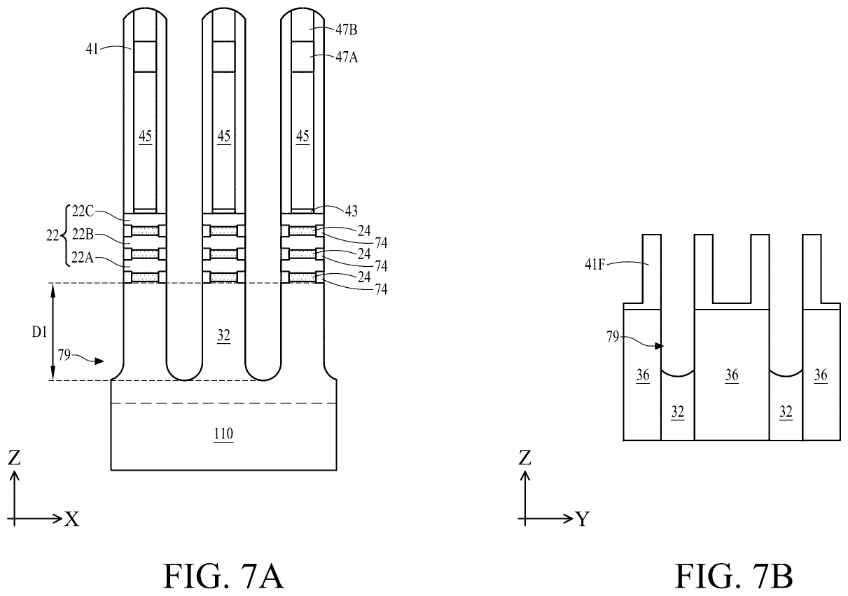

In FIGS. 7A and 7B, following formation of the inner spacer layer 74L, an etching process, such as an anisotropic etching process, is performed to remove portions of the inner spacer layer 74 disposed outside the recesses, for example, on sidewalls of the nanostructures 22 and the fins 32. The remaining portions of the inner spacer layer 74L (e.g., portions disposed inside the recesses in the nanostructures 24) form the inner spacers 74. During formation of the inner spacers 74 by the etching process, after breaking through a portion of the inner spacer layer 74L on an upper surface of the fin 32, the etching process may continue to form extended source/drain openings 79 that have depth that exceeds that of the source/drain openings 59. The resulting structure is shown in FIG. 7A.

The extended source/drain openings 79 may extend to a first depth D1 that is below an upper surface of the fins 32. The first depth D1 may be measured from a bottom surface of the lowermost inner spacer 74, as depicted. In some embodiments, the first depth D1 may be in a range of about 10 nm to about 30 nm. The isolation structure 110B that isolates source/drain(s) 82 from the substrate 110 or fin 32 is formed in the extended source/drain opening 79 in subsequent operations. The first depth D1 being less than about 10 nm may result in insufficient isolation (physical and/or electrical) between the source/drain(s) 82 and the substrate 110 or fin 32. The first depth D1 exceeding about 30 nm may result in difficulty forming layers in the extended source/drain opening 79 due to increased aspect ratio (depth/width) thereof.

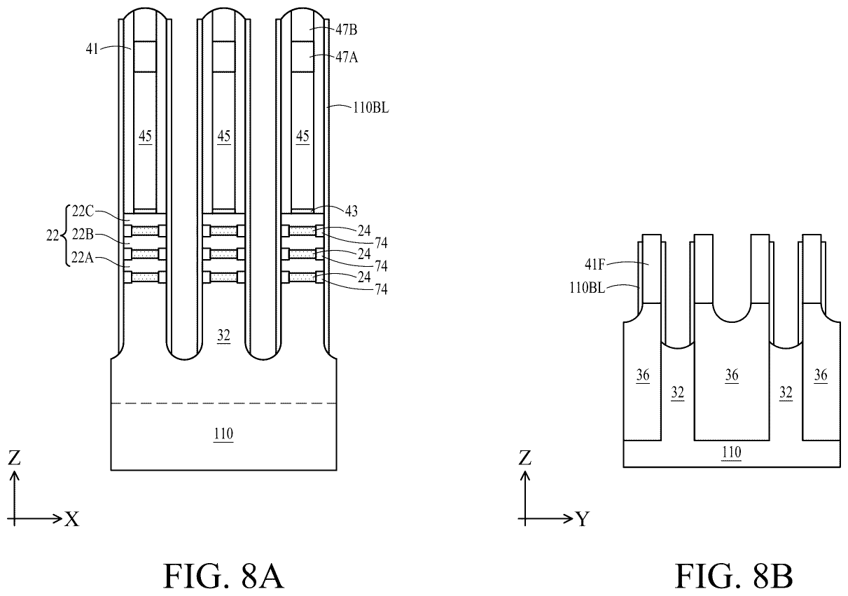

FIGS. 8A-10B depict formation of isolation structures 110B and semiconductor layers 110A or “second semiconductor layers 110A,” in accordance with various embodiments, corresponding to acts 1400 and 1500 of FIG. 25. Some portions of act 1500 may be performed prior to completing act 1400.

In FIGS. 8A, 8B, a first material layer 110BL is formed in the extended source/drain openings 79. The first material layer 110BL may be or include a material that is a dielectric and has etching selectivity that is different from the substrate 110 and fin 32. For example, the substrate 110 and fin 32 may be silicon and the first material layer 110BL may be SiN, SiOC, SiOCN, SiCN or the like. The first material layer 110BL may be deposited in the extended source/drain openings 79. The deposition may include one or more operations, such as a CVD, ALD or the like. The first material layer 110BL may be deposited to a thickness that is in a range of about 1 nm to about 3 nm. In some embodiments, following deposition of the first material layer 110BL, horizontal or curved portions of the first material layer 110BL at the bottom of the extended source/drain opening 79 may be removed, for example, by a suitable etching operation, such as a dry etch that includes a gas source including CF4, CH3F, CHF3, CH4, or the like. The first material layer 110BL may be in direct contact with side surfaces or sidewalls of the spacer layer 41, the fin spacer 41F, the channels 22, the inner spacers 74, the fin 32 and the isolation regions 36.

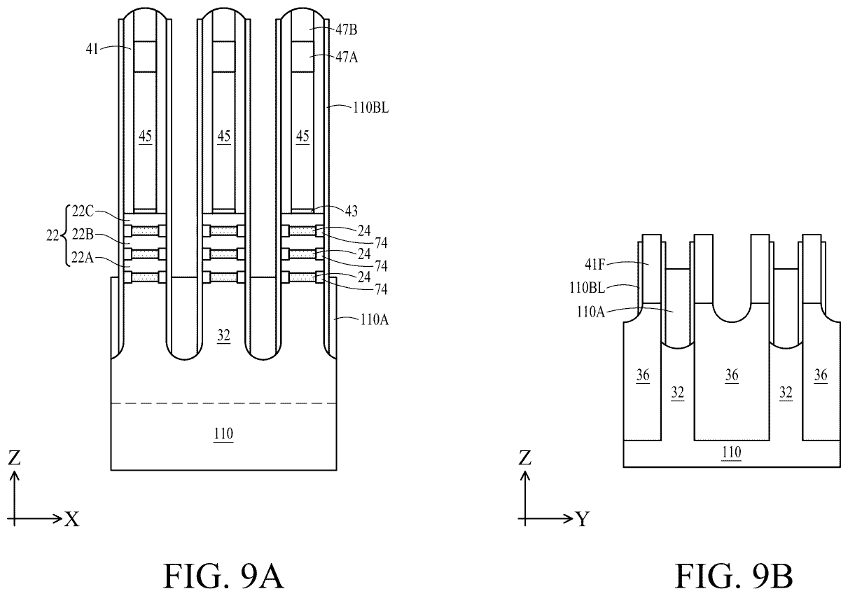

In FIGS. 9A, 9B, a first semiconductor layer 110A or “first semiconductor feature 110A” is formed on the first material layer 110BL, corresponding to act 1500 of FIG. 25. The first semiconductor layer 110A may be or include a semiconductor material, which may be an undoped semiconductor material, such as undoped silicon or undoped silicon germanium. The first semiconductor layer 110A may be formed by a suitable growth process, such as a chemical vapor deposition (CVD), molecular beam epitaxy (MPE) or the like. The first semiconductor layer 110A is a different material than the first material layer 110BL, which is beneficial to remove exposed portions of the first material layer 110BL without substantially removing the first semiconductor layer 110A. The first semiconductor layer 110A is a semiconductive material, which is beneficial to form pFET source/drains in subsequent operations that have improved strain, which improves DC performance. The first semiconductor layer 110A may have a top surface that is substantially flat, which is beneficial for forming epitaxial layers, such as source/drains 82 thereon.

In some embodiments, the first semiconductor layer 110A has an upper surface that is at a level above an upper surface of the fin 32 and optionally below a lower surface of the bottommost channel 22A and/or top surface of the bottommost inner spacer 74. The first semiconductor layer 110A may have height that is in a range of about 10 nm to about 25 nm. The first semiconductor layer 110A may be in direct contact with upper surfaces of the fin 32 in the extended source/drain openings 79 and side surfaces or sidewalls of the first material layer 110BL.

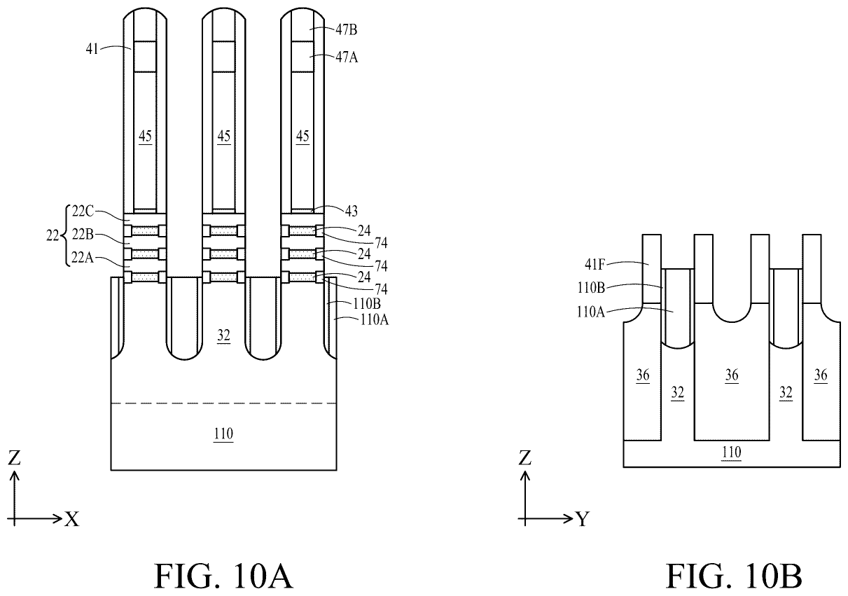

In FIGS. 10A, 10B, portions of the first material layer 110BL exposed by the first semiconductor layer 110A are removed, forming isolation structures 110B, completing act 1400 of FIG. 25. Following the removal, the isolation structures 110B may have upper surfaces that are substantially coplanar with upper surfaces of the first semiconductor layers 110A. Removing the exposed portions of the first material layer 110BL exposes the gate spacers 41, channels 22, inner spacers 74 and upper portions of the fin spacers 41F.

Removal of the exposed portions of the first material layer 110BL as depicted in FIGS. 10A, 10B may be performed via an etch process that is isotropic, such as a wet etch that includes dilute HF or an sulfuric peroxide mix (SPM) solution. In some embodiments, upper surfaces of the first material layer 110BL may be slightly recessed to a level that is below the upper surfaces of the first semiconductor layers 110A. In some embodiments, the upper surfaces of the isolation structures 110B extend to a level slightly above the upper surfaces of the first semiconductor layers 110A.

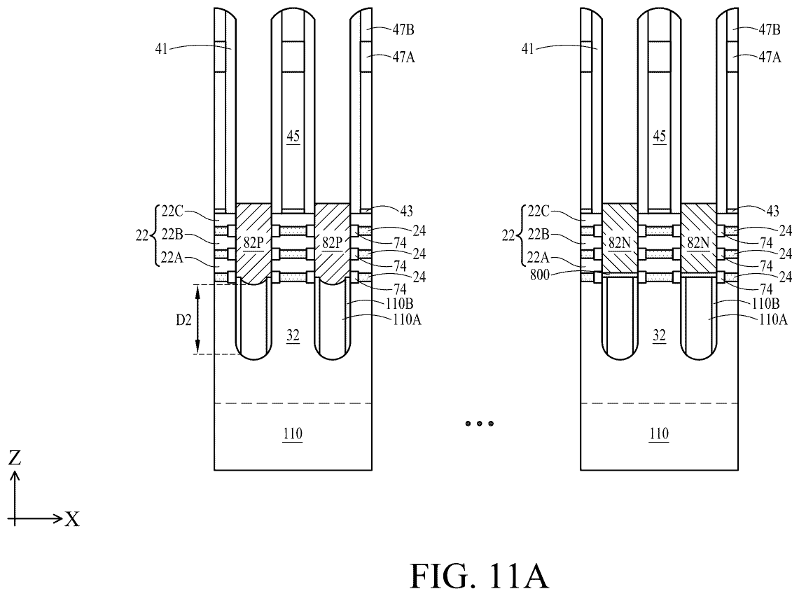

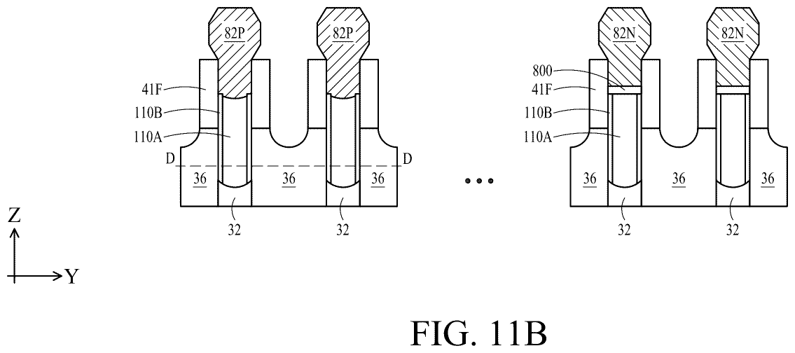

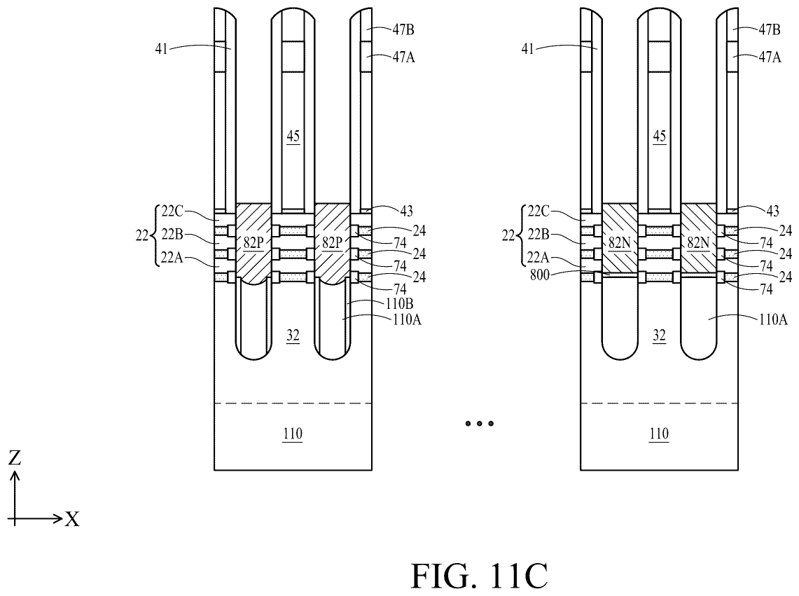

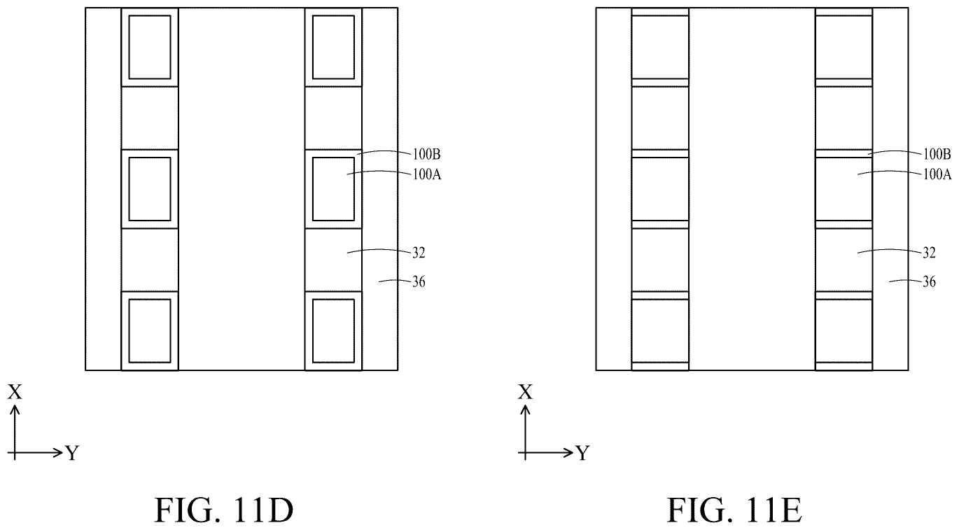

In FIGS. 11A, 11B, 11C, 11D, 11E, source/drain regions 82N, 82P are formed, corresponding to act 2000 of FIG. 25. In the illustrated embodiment, the source/drain regions 82P are epitaxially grown from epitaxial material(s). In some embodiments, the source/drain regions 82P exert stress in the respective channels 22A, 22B, 22C, thereby improving performance. The source/drain regions 82P are formed such that each dummy gate structure 40 is disposed between respective neighboring pairs of the source/drain regions 82P. In some embodiments, the spacer layer 41 separates the source/drain regions 82P from the dummy gate layer 45 by an appropriate lateral distance to prevent electrical bridging to subsequently formed gates of the resulting device. The source/drain regions 82P may be or include Si:B, Si:Ga, SiGe:B, SiGe:B:Ga, SiGe:Sn, SiGe:B:Sn or the like. The source/drain regions 82P may exert a compressive strain in the channel regions. The source/drain regions 82N, 82P may have surfaces raised from respective surfaces of the first semiconductor layer 110A and may have facets. Neighboring source/drain regions 82P may merge in some embodiments to form a singular source/drain region 82P adjacent two neighboring fins 32.

In the illustrated embodiment, following formation of the source/drain regions 82P, the optional bottom insulator 800 may be formed, corresponding to act 1900 of FIG. 25. Formation of the bottom insulator 800 may include a suitable deposition operation, such as an LPCVD, PECVD, ALD, or the like. The bottom insulator 800 may be or include SiN or another suitable dielectric material. Thickness of the bottom insulator 800 may be in a range of about 2 nm to about 4 nm. During formation of the bottom insulator 800, a dielectric layer having the same composition and thickness as the bottom insulator 800 may be formed on the upper surface of the source/drain regions 82P. The dielectric layer may be removed from the upper surface of the source/drain regions 82P, as shown. In some embodiments, the bottom insulator 800 is not formed, such that the source/drain regions 82N formed in a subsequent operation are formed directly on the first semiconductor layer 110A.

Following formation of the bottom insulator 800, the source/drain regions 82N are epitaxially grown from epitaxial material(s). In embodiments including the optional bottom insulator 800, the source/drain regions 82N may grow from the channels 22 without growing from the first semiconductor layer 110A. In some embodiments, the source/drain regions 82N exert stress in the respective channels 22A, 22B, 22C, thereby improving performance. The source/drain regions 82N are formed such that each dummy gate structure 40 is disposed between respective neighboring pairs of the source/drain regions 82N. In some embodiments, the spacer layer 41 separates the source/drain regions 82N from the dummy gate layer 45 by an appropriate lateral distance to prevent electrical bridging to subsequently formed gates of the resulting device. The source/drain regions 82N may be or include SiP, SiAs, SiSb, SiPAs, SiP:As:Sb or the like. The source/drain regions 82N may exert a tensile strain in the channel regions due to presence of the bottom insulator 800. The source/drain regions 82N may have surfaces raised from respective surfaces of the fins 32 and may have facets. Neighboring source/drain regions 82N may merge in some embodiments to form a singular source/drain region 82N adjacent two neighboring fins 32.

As depicted in FIG. 11A, the isolation structures 110B may extend to a second depth D2 below the bottom surface of the source/drain regions 82P. Namely, the second depth D2 is a distance between the bottommost point of the bottom surface of the source/drain region 82P to a bottommost point of a bottom surface of the isolation structure 110B. In some embodiments, the second depth D2 is in a range of about 5 nm to about 20 nm. The second depth D2 being less than about 5 nm may result in insufficient isolation between the source/drain 82 and the substrate 110 and/or fin 32.

In some embodiments, as depicted in FIG. 11C, the isolation structures 110B are formed in PFETs and are not formed in NFETs. For example, under the p-type source/drains 82P, the isolation structures 110B are positioned between the first semiconductor layer 110A and the adjacent substrate 110 and/or fin 32, and under the n-type source/drains 82N, the isolation structures 110B are omitted, such that the first semiconductor layer 110A is in direct contact with the upper and side surfaces or sidewalls of the substrate 110 and/or fin 32. In such embodiments, the bottom insulator 800 is present between the source/drains 82N and the first semiconductor layer 110A.

FIG. 11D depicts a cross-sectional top view of the device 10 along the line D-D depicted in FIG. 11B in the XY plane. The isolation structures 110B fully surround the first semiconductor layer 110A along at least four sides, such as front, back, left and right sides. “Fully surround” includes the meaning that fewer than all sides of the first semiconductor layer 110A are surrounded. For example, top and bottom surfaces of the first semiconductor layer 110A may not be surrounded by the isolation structures 110B.

As depicted in FIG. 11E, in some embodiments, the first semiconductor layer 110A may be directly abutting the isolation regions 36, and the isolation structure 110B may be omitted on one or more side surfaces of the first semiconductor layer 110A that abut the isolation region(s) 36. Namely, because the isolation regions 36 are electrical insulators, formation of the isolation structure 110B between the first semiconductor layer and the isolation regions 36 may be omitted.

In FIGS. 12A, 12B, following formation of the source/drain regions 82N, 82P, the ILD 130 may be formed covering the source/drain regions 82N, 82P and abutting the spacer layer 41 (see FIG. 12B). In some embodiments, the ESL 131 is formed prior to forming the ILD 130. The ESL 131 may be formed by depositing a conformal thin layer of a dielectric material different from that of the ILD 130, such as one or more of SiN, SiCN, SiC, SiOC, SiOCN, HfO2, ZrO2, ZrAlOx, HfAlOx, HfSiOx, Al2O3, or other suitable material. Following deposition of the ESL 131, the ILD 130 may be deposited by a suitable process, such as a blanket deposition process, including PVD, CVD, ALD, or the like. The material of the ILD 130 may include silicon dioxide or a low-k dielectric material (e.g., a material having a dielectric constant (k-value) lower than the k-value (about 3.9) of silicon dioxide). The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOxCy), Spin-On-Glass (SOG) or a combination thereof. The ILD may be deposited by spin-on coating, CVD, Flowable CVD (FCVD), PECVD, PVD, or another deposition process.

Then, active gate structures 200 may be formed. A planarization process, such as a chemical mechanical polishing (CMP) process, is performed on the ILD 130 and the ESL 131. The hard masks 47A, 47B and portions of the gate spacers 41 are also removed in the planarization process. After the planarization process, the dummy gate layers 45 are exposed. The top surfaces of the ILD 130 and the ESL 131 may be coplanar with the top surfaces of the dummy gate layers 45 and the gate spacers 41.

Next, the dummy gate layer 45 is removed in an etching process, so that recesses are formed. In some embodiments, the dummy gate layer 45 is removed by an anisotropic dry etch process. For example, the etching process may include a dry etch process using reaction gas(es) that selectively etch the dummy gate layer 45 without etching the spacer layer 41. The dummy gate dielectric 43, when present, may be used as an etch stop layer when the dummy gate layer 45 is etched. The dummy gate dielectric 43 may then be removed after the removal of the dummy gate layer 45.

The nanostructures 24 are removed to release the nanostructures 22. After the nanostructures 24 are removed, the nanostructures 22 form a plurality of nanosheets that extend horizontally (e.g., parallel to a major upper surface of the substrate 110). In some embodiments, the nanostructures 24 are removed by a selective etching process using an etchant that is selective to the material of the nanostructures 24, such that the nanostructures 24 are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like.

In some embodiments, the nanostructures 24 are removed and the nanostructures 22 are patterned to form channel regions of both PFETs and NFETs. However, in some embodiments the nanostructures 24 may be removed and the nanostructures 22 may be patterned to form channel regions of NFETs, and nanostructures 22 may be removed and the nanostructures 24 may be patterned to form channel regions of PFETs. In some embodiments, the nanostructures 22 may be removed and the nanostructures 24 may be patterned to form channel regions of NFETs, and the nanostructures 24 may be removed and the nanostructures 22 may be patterned to form channel regions of PFETs. In some embodiments, the nanostructures 22 may be removed and the nanostructures 24 may be patterned to form channel regions of both PFETs and NFETs.

In some embodiments, the nanosheets 22 are reshaped (e.g. thinned) by a further etching process to improve gate fill window. The reshaping may be performed by an isotropic etching process selective to the nanosheets 22. After reshaping, the nanosheets 22 may exhibit the dog bone shape in which middle portions of the nanosheets 22 are thinner than peripheral portions of the nanosheets 22 along the X direction.

Then, replacement gates 200 are formed. The gate structures 200 may be formed by a series of deposition operations, such as ALD cycles, that deposit the various layers of the gate structure 200 in the openings, described in greater detail with reference to FIG. 24.

FIG. 24 is a detailed view of a portion of the gate structure 200. The gate structure 200 generally includes the interfacial layer (IL, or “first IL” below) 210, at least one gate dielectric layer 600, the work function metal layer 900, and the gate fill layer 290. In some embodiments, each replacement gate 200 further includes at least one of a second interfacial layer 240 or a second work function layer 700.

With reference to FIG. 24, in some embodiments, the first IL 210 includes an oxide of the semiconductor material of the substrate 110, e.g. silicon oxide. In other embodiments, the first IL 210 may include another suitable type of dielectric material. The first IL 210 has a thickness in a range between about 5 angstroms and about 50 angstroms.

Still referring to FIG. 24, the gate dielectric layer 600 is formed over the first IL 210. In some embodiments, an atomic layer deposition (ALD) process is used to form the gate dielectric layer 600 to control thickness of the deposited gate dielectric layer 600 with precision. In some embodiments, the ALD process is performed using between about 40 and 80 deposition cycles, at a temperature range between about 200 degrees Celsius and about 300 degrees Celsius. In some embodiments, the ALD process uses HfCl4 and/or H2O as precursors. Such an ALD process may form the first gate dielectric layer 220 to have a thickness in a range between about 10 angstroms and about 100 angstroms.

In some embodiments, the gate dielectric layer 600 includes a high-k dielectric material, which may refer to dielectric materials having a high dielectric constant that is greater than a dielectric constant of silicon oxide (k≈3.9). Exemplary high-k dielectric materials include HfO₂, HfSiO, HfSiON, HfTaO, HfTiO, HfZrO, ZrO₂, Ta₂O₅, or combinations thereof. In other embodiments, the gate dielectric layer 600 may include a non-high-k dielectric material such as silicon oxide. In some embodiments, the gate dielectric layer 600 includes more than one high-k dielectric layer, of which at least one includes dopants, such as lanthanum, magnesium, yttrium, or the like, which may be driven in by an annealing process to modify threshold voltage of the nanostructure devices 20A, 20B.

With further reference to FIG. 24, the second IL 240 is formed on the gate dielectric layer 600, and the second work function layer 700 is formed on the second IL 240. The second IL 240 promotes better metal gate adhesion on the gate dielectric layer 600. In many embodiments, the second IL 240 further provides improved thermal stability for the gate structure 200, and serves to limit diffusion of metallic impurity from the work function metal layer 900 and/or the work function barrier layer 700 into the gate dielectric layer 600. In some embodiments, formation of the second IL 240 is accomplished by first depositing a high-k capping layer (not illustrated for simplicity) on the gate dielectric layer 600. The high-k capping layer comprises one or more of the following: HfSiON, HfTaO, HfTiO, HfTaO, HfAlON, HfZrO, or other suitable materials, in various embodiments. In a specific embodiment, the high-k capping layer comprises titanium silicon nitride (TiSiN). In some embodiments, the high-k capping layer is deposited by an ALD using about 40 to about 100 cycles at a temperature of about 400 degrees C. to about 450 degrees C. A thermal anneal is then performed to form the second IL 240, which may be or comprise TiSiNO, in some embodiments. Following formation of the second IL 240 by thermal anneal, an atomic layer etch (ALE) with artificial intelligence (AI) control may be performed in cycles to remove the high-k capping layer while substantially not removing the second IL 240. Each cycle may include a first pulse of WCl₅, followed by an Ar purge, followed by a second pulse of O₂, followed by another Ar purge. The high-k capping layer is removed to increase gate fill window for further multiple threshold voltage tuning by metal gate patterning.

Further in FIG. 24, after forming the second IL 240 and removing the high-k capping layer, the work function barrier layer 700 is optionally formed on the gate structure 200, in accordance with some embodiments. The work function barrier layer 700 is or comprises a metal nitride, such as TiN, WN, MoN, TaN, or the like. In a specific embodiment, the work function barrier layer 700 is TiN. The work function barrier layer 700 may have thickness ranging from about 5 A to about 20 A. Inclusion of the work function barrier layer 700 provides additional threshold voltage tuning flexibility. In general, the work function barrier layer 700 increases the threshold voltage for NFET transistor devices, and decreases the threshold voltage (magnitude) for PFET transistor devices.

The work function metal layer 900, which may include at least one of an N-type work function metal layer, an in-situ capping layer, or an oxygen blocking layer, is formed on the work function barrier layer 700, in some embodiments. The N-type work function metal layer is or comprises an N-type metal material, such as TiAlC, TiAl, TaAlC, TaAl, or the like. The N-type work function metal layer may be formed by one or more deposition methods, such as CVD, PVD, ALD, plating, and/or other suitable methods, and has a thickness between about 10 A and 20 A. The in-situ capping layer is formed on the N-type work function metal layer. In some embodiments, the in-situ capping layer is or comprises TiN, TiSiN, TaN, or another suitable material, and has a thickness between about 10 A and 20 A. The oxygen blocking layer is formed on the in-situ capping layer to prevent oxygen diffusion into the N-type work function metal layer, which would cause an undesirable shift in the threshold voltage. The oxygen blocking layer is formed of a dielectric material that can stop oxygen from penetrating to the N-type work function metal layer, and may protect the N-type work function metal layer from further oxidation. The oxygen blocking layer may include an oxide of silicon, germanium, SiGe, or another suitable material. In some embodiments, the oxygen blocking layer is formed using ALD and has a thickness between about 10 A and about 20 A.

FIG. 24 further illustrates the metal core layer 290. In some embodiments, a glue layer (not separately illustrated) is formed between the oxygen blocking layer of the work function metal layer and the metal core layer 290. The glue layer may promote and/or enhance the adhesion between the metal core layer 290 and the work function metal layer 900. In some embodiments, the glue layer may be formed of a metal nitride, such as TiN, TaN, MoN, WN, or another suitable material, using ALD. In some embodiments, thickness of the glue layer is between about 10 A and about 25 A. The metal core layer 290 may be formed on the glue layer, and may include a conductive material such as tungsten, cobalt, ruthenium, iridium, molybdenum, copper, aluminum, or combinations thereof. In some embodiments, the metal core layer 290 may be deposited using methods such as CVD, PVD, plating, and/or other suitable processes. In some embodiments, a seam 510, which may be an air gap, is formed in the metal core layer 290 vertically between the channels 22A, 22B, 22C. In some embodiments, the metal core layer 290 is conformally deposited on the work function metal layer 900. The seam 510 may form due to sidewall deposited film merging during the conformal deposition. In some embodiments, the seam 510 is not present between the neighboring channels 22A, 22B, 22C.

Following formation of the gate structures 200, source/drain openings may be formed in the ILD 130 and source/drain contacts 120 may be formed in the source/drain openings. The resulting structure is shown in FIGS. 12A, 12B.

Silicide regions 118 and the source/drain contacts 120 may be formed on the source/drain regions 82N, 82P. In some embodiments, the silicide layers 118 are formed prior to formation of the source/drain contacts 120. For example, an N-type or P-type metal layer may be formed as a conformal thin layer over exposed portions of the source/drain regions 82N, 82P. The metal layer may be or include one or more of Ni, Co, Mn, W, Fe, Rh, Pd, Ru, Pt, Ir, Os or the like. In some embodiments, the metal layer is or includes one or more of Ti, Cr, Ta, Mo, Zr, Hf, Sc, Ys, Ho, Tb, Gd, Lu, Dy, Er, Yb or another suitable material. Following formation of the metal layer, the silicide layers 118 may be formed by annealing the device 10. Following the anneal, the silicide layers 118 may be or include one or more of NiSi, CoSi, MnSi, WSi, FeSi, RhSi, PdSi, RuSi, PtSi, IrSi, OsSi, TiSi, CrSi, TaSi, MoSi, ZrSi, HfSi, ScSi, YSi, HoSi, TbSi, GdSi, LuSi, DySi, ErSi, YbSi or the like. Silicide of the silicide layers 118 may diffuse into regions below the ESL 131. Thickness of the silicide layers 118 may be in a range of about 1 nm to about 10 nm. Below about 1 nm, contact resistance may be too high. Above about 10 nm, the silicide layers 118 may short with the channels 22B.

Following formation of the silicide layers 118, the source/drain contacts 120 are formed by filling the openings over the source/drain regions 82N, 82P with, for example, a liner layer and a fill layer. In some embodiments, the source/drain contacts 120 are formed by depositing a material that is or includes a conductive material such as Co, W, Ru, combinations thereof, or the like. In some embodiments, the source/drain contacts 120 are or include a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. The source/drain contacts 120 land on the silicide layer 118 and are in contact with the ESL 131. Description of the device 10 and illustration thereof in many of the figures is given with reference to GAAFETs including vertical stacks of the nanostructures 22. In some embodiments, the silicide layers 118 and the source/drain contacts 120 are formed in and on source/drain regions 82N, 82P of FinFET devices.

Additional processing may be performed to finish fabrication of the nanostructure devices 20. For example, gate contacts (or gate vias) may be formed to electrically couple to the gate structures 200. An interconnect structure may then be formed over the source/drain contacts 120 and the gate contacts. The interconnect structure may include a plurality of dielectric layers (including, for example, a second ILD) surrounding metallic features, including conductive traces and conductive vias, which form electrical connection between devices on the substrate 110, such as the nanostructure devices 20, as well as to IC devices external to the IC device 10.

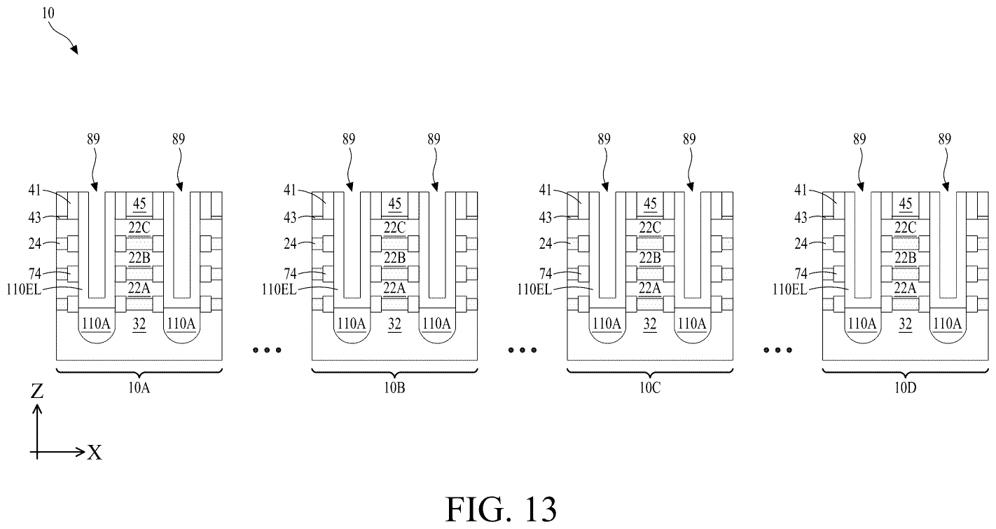

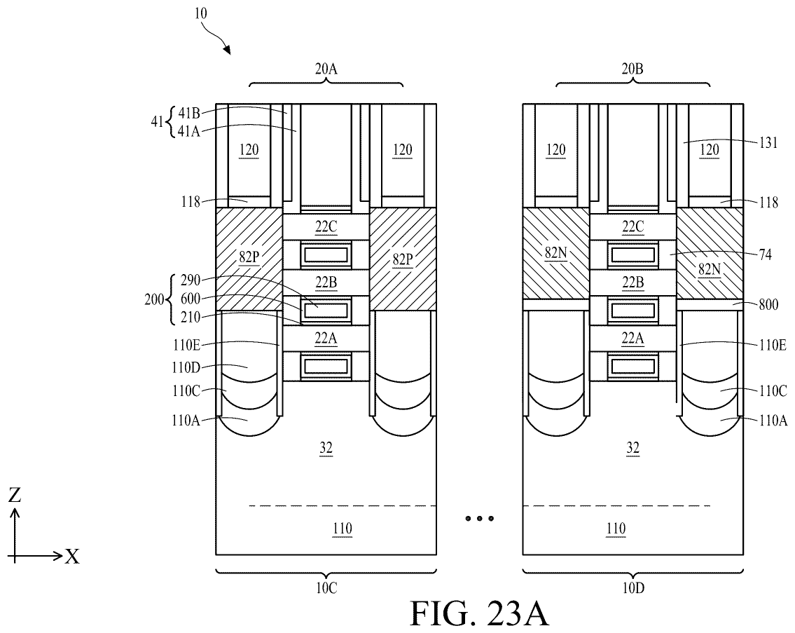

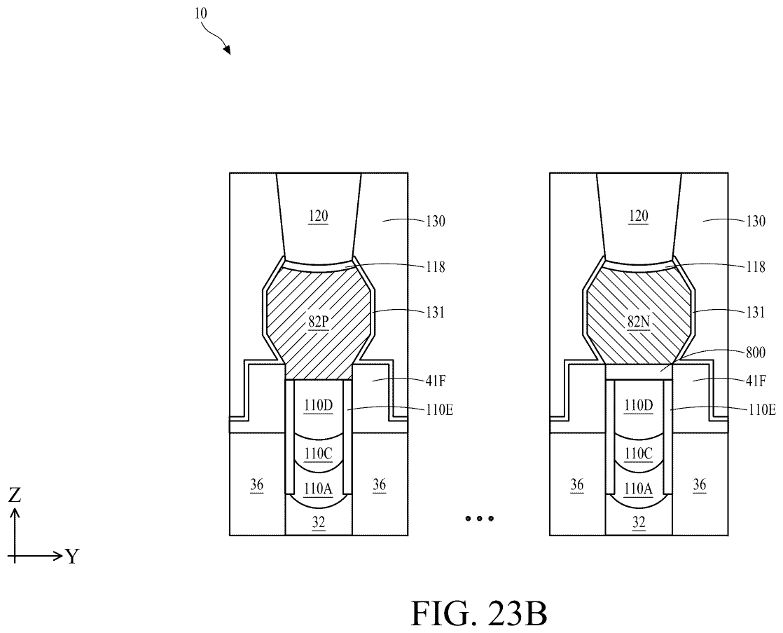

FIGS. 13-23B are cross-sectional side views depicting formation of an implantation region 110C having anti-dopants therein in accordance with various embodiments. Like reference numerals refer to like elements. Description of the embodiments depicted in FIGS. 13-22 is provided with reference to configurations in which the isolation structures 110B are not formed. In some embodiments, formation of the isolation structures 110B may be combined with formation of the implantation regions 110C, which is depicted in FIGS. 23A an 23B. It should be understood that “combined” includes the meaning that the isolation structures 110B are formed in an operation that precedes or follows formation of the implantation regions 110C.

In FIG. 13, following formation of the first semiconductor layer or mesa 110A that is in direct contact with the adjacent fin 32 and/or substrate 110, an isolating layer 110EL is formed in source/drain openings 89 in first, second, third and fourth device regions 10A, 10B, 1° C., 10D, corresponding to act 1600 of FIG. 25. The first and second device regions 10A, 10B may be regions in which three of the channels 22 are active, and the third and fourth device regions 10C, 10D may be regions in which two of the channels 22 are active and one of the channels 22 is disabled. The first and third device regions 10A, 1° C. may be regions in which NFETs are formed, and the second and fourth device regions 10B, 10D may be regions in which PFETs are formed.

The isolating layer 110EL may be a dielectric material layer, which may be or include one or more of SiOC, SiOCN, SiCN, SiN and the like. The isolation layer 110EL may be deposited as a conformal thin layer on exposed surfaces of the spacers 41, the channels 22, the inner spacers 74 and the first semiconductor layer 110A. The isolation layer 110EL may be deposited by a suitable deposition operation, such as a PVD, CVD, ALD or the like. The isolation layer 110EL may have first thickness in a range of about 1 nm to about 10 nm.

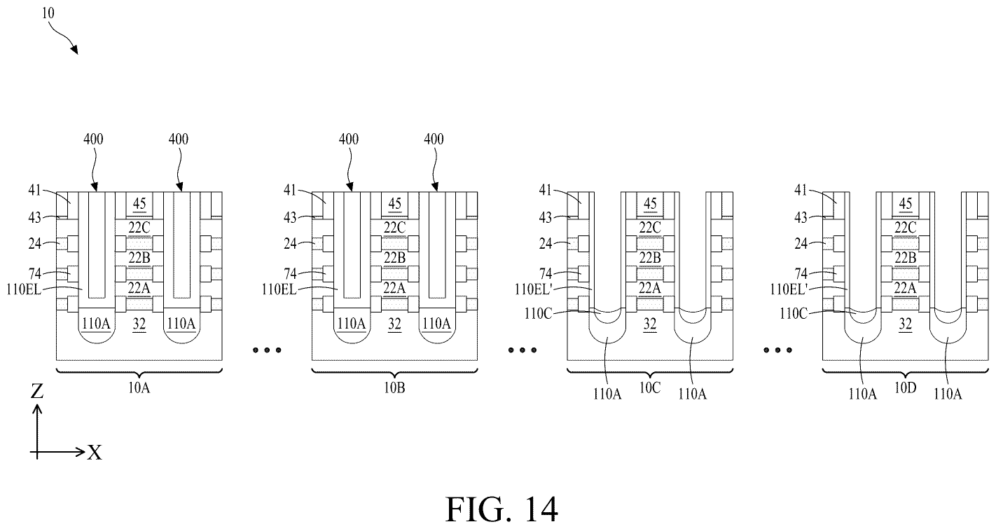

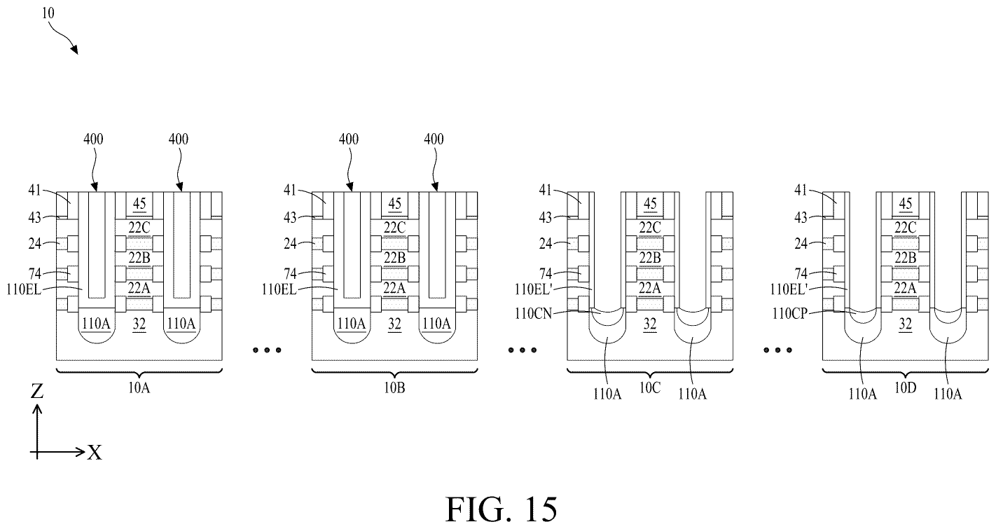

In FIGS. 14 and 15, following formation of the isolation layer 110EL, a mask layer 400 is formed that covers the isolation layer 110EL in the first and second device regions 10A, 10B while exposing the isolation layer 110EL in the third and fourth device regions 10C, 10D. The mask layer 400 may be blanket coated on the device regions 10A-10D, then patterned to expose the third and fourth device regions 10C, 10D. Then, portions of the device regions 10A-10D exposed by the mask layer 400 are etched by a suitable etching process. For example, the isolation layer 110EL in the third and fourth device regions 10C, 10D is etched in the etching process, which breaks through (or removes) a bottom portion of the isolation layer 110EL to expose the underlying first semiconductor layer 110A. In some embodiments, the upper surface of the first semiconductor layer 110A is etched slightly by the etching process, which may result in the upper surface being concave following the etching process. Thickness of the isolation layer 110EL′ that remains on the side surfaces or sidewalls of the spacer 41, inner spacers 74 and channels 22 may be reduced by the etching process. In some embodiments, following the etching process, the thickness of the isolation layer 110EL′ is in a range of about 1 nm to about 3 nm. The etching process may be a wet etch that is selective to material of the isolation layer 110EL′, in some embodiments.

Following removal of the bottom portion of the isolation layer 110EL to expose the first semiconductor layer 110A, as depicted in FIG. 14, an implantation process may be performed that forms implantation regions 10C in the first semiconductor layer 110A in the third and fourth device regions 10C, 10D, corresponding to act 1700 of FIG. 25. In some embodiments, the implantation process implants “anti-dopants” in the implantation regions 110C, which may be dopants of a different or opposite type than the source/drains 82 that will be formed over the implantation regions 110C. For example, the third device region 10C may include P-type nanostructure devices 20A (shown in FIG. 23A) that have P-type source/drains 82P, and the implantation regions 110C in the third and fourth device regions 10C, 10D may include N-type ion dopant species, such as P, As, Sb, Bi or the like. In another example, the third and fourth device regions 10C, 10D may include N-type nanostructure devices that have N-type source/drains 82N, and the implantation regions 110C may include P-type ion dopant species, such as B, Al, Ga, In or the like.

In some embodiments, as depicted in FIG. 15, the third device region 10C will include P-type nanostructure devices and the fourth device region 10D will include N-type nanostructure devices. In such embodiments, an implantation region 110CN in the third device region 10C underlying the P-type nanostructure device may include N-type ion dopant species, such as P, As, Sb, Bi or the like, and an implantation region 110CP in the fourth device region 10D underlying the N-type nanostructure device may include P-type ion dopant species, such as B, Al, Ga, In or the like. For example, the third device region 10C may be masked while a first implantation process implants the P-type ions in the fourth device region 10D, then the fourth device region 10D may be masked while a second implantation process implants the N-type ions in the third device region 10C.

In some embodiments, the third device region 10C that will include P-type nanostructure devices is implanted with N-type ions to form the implantation region 110CN and the fourth device region 10D that will include N-type nanostructure devices does not undergo implantation. For example, the implantation region 110CN may be formed in P-type device regions and the implantation region 110CP is omitted in N-type device regions. When the implantation region 110C or 110CP is omitted, the first semiconductor layer 110A may be a single, continuous layer that is undoped throughout and is in direct contact with source/drains 82N formed thereon or is in direct contact with a bottom insulator 800 that is between the first semiconductor layer 110A and the source/drain 82N formed thereon.

The implantation process(es) may include a first cleaning process in which the exposed regions are cleaned to remove surface contaminants, which may include immersing the wafer in one or more chemicals and rinsing the wafer with deionized water. Then, a thin oxide layer may optionally be grown on the trench walls and bottom to improve dopant diffusion and prevent channeling effects. An implantation operation may be performed in which the selected dopant species (e.g., phosphorus for n-type, boron for p-type) is ionized and accelerated to high energy (e.g., 10-100 keV). The ion beam is directed at the exposed regions, with parameters selected that are beneficial to achieve conformal doping in the high aspect ratio trenches. In some embodiments, the wafer is tilted and/or multiple ion beams are directed at the wafer. Dosage and energy of the ion beam may be selected to achieve selected dopant concentration and profile within the trenches. The implanted wafer may then be annealed at high temperatures (e.g., 800-1000° C.) to activate the dopant and remove implantation damage. The annealing process may also affect dopant diffusion and activation profile. Then, a post-implantation clean may be performed that removes post-implantation residues.

The implantation region 110C may extend from a first side surface of the isolation layer 110EL′ to an opposite second side surface of the isolation layer 110EL′. The implantation region 110C may extend to a depth that is below a lower surface of the bottommost inner spacer 74 and above a bottom surface of the first semiconductor layer 110A.

Inclusion of the implantation region 110C, 110CP, 110CN including the anti-dopants may be beneficial to reduce leakage current and thereby reduce effective capacitance Ceff.

Although the implantation regions 110C, 110CP, 110CN are depicted in FIGS. 14 and 15 as only being present in the third and fourth device regions 10C, 10D corresponding to 2-sheet devices, it should be understood that the implantation regions 110C, 110CP, 110CN may be formed in all four device regions 10A-10D in some embodiments. Namely, following formation of the layer 110EL, the mask layer 400 may not be formed, and the layer 110EL may be thinned in all of the device regions 10A-10D, such that 3-sheet devices in the first and second device regions 10A, 10B and 2-sheet devices in the third and fourth device regions 10C, 10D may each include the implantation regions 110C, 110CP, 110CN.

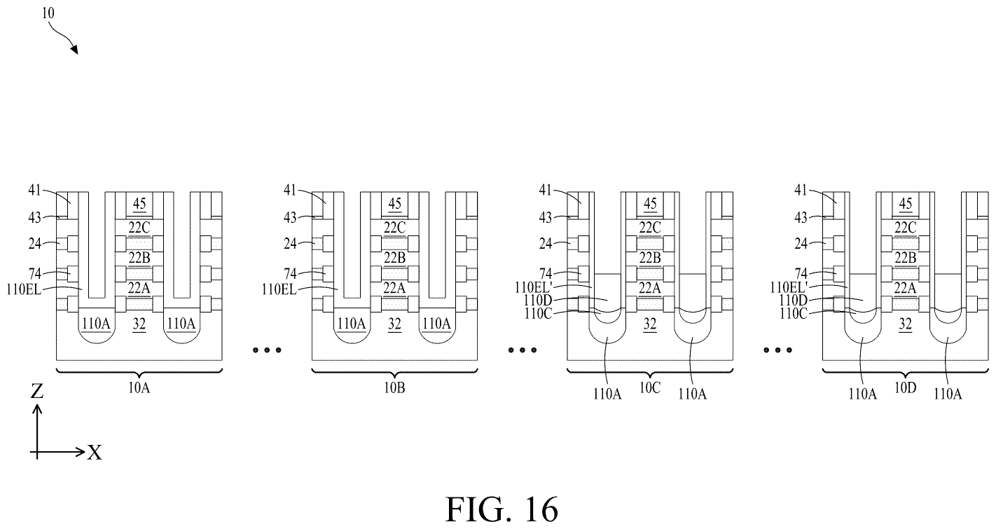

In FIG. 16, the mask layer 400 may be removed, then a second semiconductor layer 110D, which may be an undoped semiconductor layer, such as an undoped silicon layer, is formed on the implantation regions 110C, corresponding to act 1800 of FIG. 25. The undoped silicon layer may be formed by a suitable epitaxy operation, such as a reduced-pressure CVD (RPCVD), ultra-high-vacuum CVD (UHVCVD), MBE, selective epitaxial growth (SEG) or the like. The second semiconductor layer 110D is formed to a level that is sufficiently high to isolate one or more of the channels 22. For example, as depicted in FIG. 16, the second semiconductor layer 110D is formed to a level that is above an upper surface of the bottommost channels 22A. This will serve to deactivate or disable the channels 22A while allowing the channels 22B, 22C to remain active. In some embodiments, the second semiconductor layer 110D is formed to a level that is above an upper surface of another channel 22, such as the channel 22B, such that the channels 22A and 22B may be disabled. Generally, the level may be between upper and lower surfaces of one of the inner spacers 74, such as the inner spacer 74 between the channels 22A and 22B or between the channels 22B and 22C.

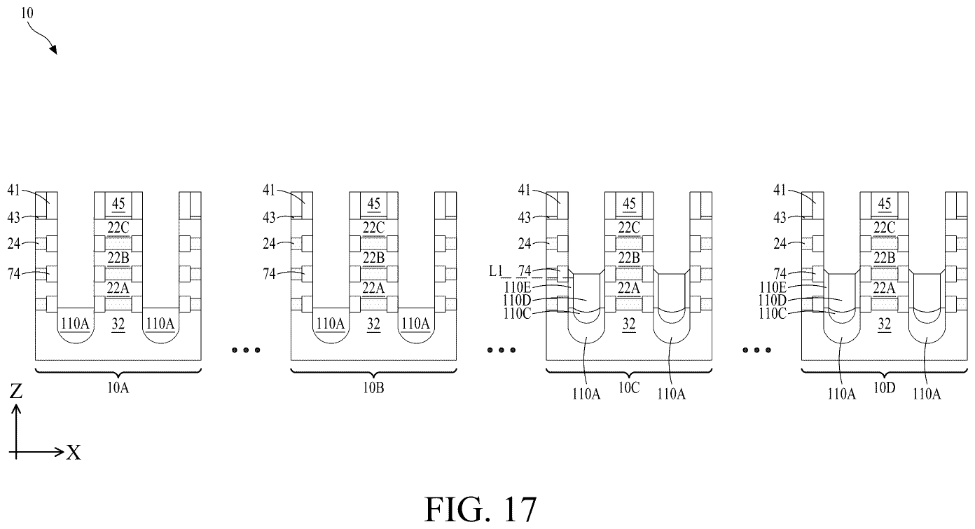

In FIG. 17, following formation of the second semiconductor layer 110D, exposed portions of the isolation layers 110EL, 110EL′ are removed, thereby exposing the first semiconductor layer 110A in the first and second device regions 10A, 10B and the second semiconductor layer 110D in the third and fourth device regions 10C, 10D. The removal may be performed by a suitable etching operation, such as a wet etch that is selective to material of the isolation layers 110EL, 110EL′. In the third and fourth device regions 10C, 10D, remaining portions of the isolation layers 110EL′ are isolation structures 110E, corresponding to act 1600 of FIG. 25. The isolation structures 110E are positioned between the channels 22A and the second semiconductor layer 110D. As depicted in FIG. 17, the isolation structure 110E may extend to a level that is slightly above or at an upper surface of the second semiconductor layer 110D. In some embodiments, the isolation structure 110E may extend to a level that is slightly below the upper surface of the second semiconductor layer 110D. For example, the etching operation that removes the exposed regions of the isolation layer 110EL′ may result in an overetch that removes a portion of the isolation layer 110EL′ that is laterally between the second semiconductor layer 110D and the adjacent inner spacer and/or channel 22A. This is depicted in FIG. 17 by a level L1 that is between the upper surface of the second semiconductor layer 110D and the lower surface of the inner spacer 74 between the channels 22A, 22B. In some embodiments, the isolation structure 110E extends to the level L1 instead of to a level above or at the upper surface of the second semiconductor layer 110D.

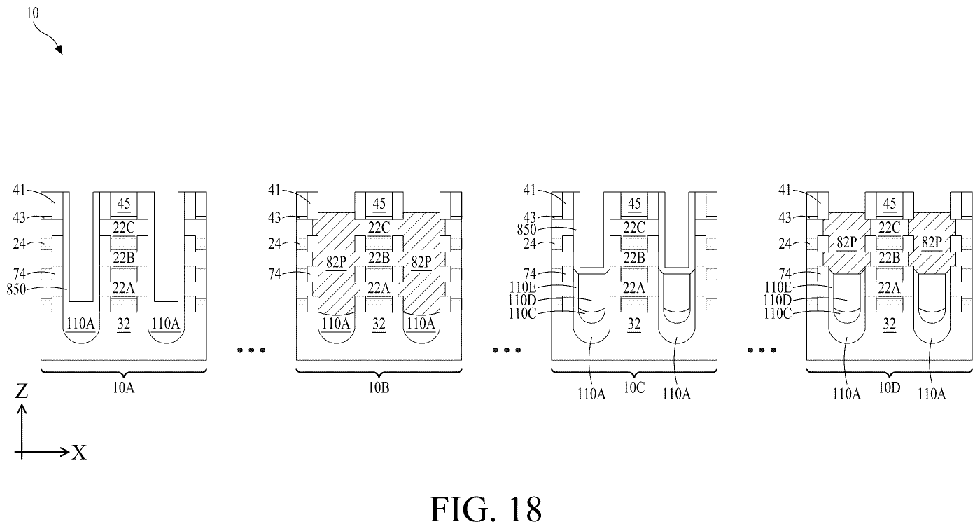

In FIG. 18, a second mask layer 850 is formed that covers regions 10A, 1° C. in which N-type nanostructure devices will be formed while exposing regions 10B, 10D in which P-type nanostructure devices will be formed. Then, P-type source/drains 82P are formed in the second and fourth device regions 10B, 10D, corresponding to act 2000 of FIG. 25. The source/drains 82P are formed on the first semiconductor layer 110A in the second device region 10B and on the second semiconductor layer 110D in the fourth device region 10D. Formation of the source/drains 82P may be performed by a suitable epitaxial growth process, such as chemical vapor deposition (CVD), atomic layer deposition (ALD), vapor phase epitaxy (VPE), molecular beam epitaxy (MBE), or the like. In the second device region 10B, the source/drains 82P are in contact with the channels 22A, 22B, 22C. In the fourth device region 10D, the source/drains 82P are in contact with the channels 22B, 22C and are isolated from the channels 22A, for example, by the isolation structure 110E. The source/drains 82P in the fourth device region 10D are isolated from the substrate 110 and/or the fins 32 by the implantation region 110C. The source/drains 82P in the second device region 10B are in direct contact with the first semiconductor layer 110A and not isolated from the substrate 110 and/or fins 32 by an implantation region, due to the implantation regions 110C not being formed in the second device region 10B.

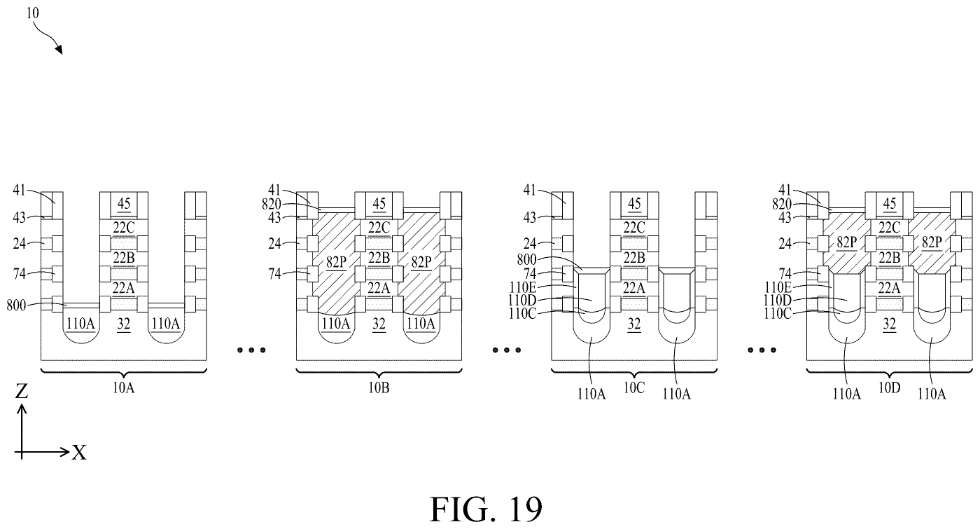

In FIG. 19, following formation of the source/drains 82P, the second mask layer 850 is removed, then the bottom isolation layer 800 is formed, which also results in dielectric layer 820 being formed on the source/drains 82P, corresponding to act 1900 of FIG. 25. The bottom isolation layer 800 and the dielectric layer 820 may be formed by depositing a single material layer, such as a dielectric layer including SiOC, SiOCN, SiCN, SiN, or the like, as a blanket conformal layer over the device regions 10A-10D, then removing excess portions of the material layer overlying the gate spacers 41 and the sacrificial gates 45, leaving horizontal portions covering upper surfaces of the first semiconductor layer 110A, the source/drains 82P and the second semiconductor layer 110D and isolation structure 110E. In some embodiments, the bottom isolation layer 800 and the isolation structure 110E include different materials. In some embodiments, the bottom isolation layer 800 and the isolation structure 110E have a visible interface therebetween. The interface may be positioned at the level L1 described with reference to FIG. 17. The bottom isolation layer 800 may be beneficial in the first device region 10A and the third device region 10C in which NFET nanostructure devices are to be formed to constrain growth of N-type source/drains 82N to lateral growth outward from the channels 22 without substantially growing upward from the substrate 110, e.g., from the first or second semiconductor layer 110A, 110D. This can improve strain in the channels 22 that is beneficial for N-type devices, such as N-type GAAFETs or the like. In some embodiments, the bottom isolation layer 800 and/or dielectric layer 820 are omitted or not formed and are not present between the source/drains 82N and the first and/or second semiconductor layers 110A, 110D.

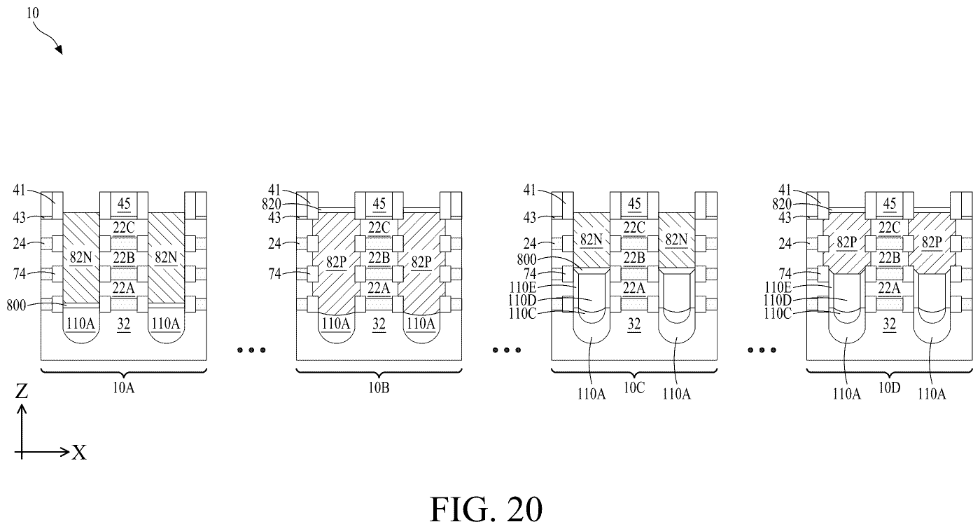

In FIG. 20, N-type source/drains 82N are formed following formation of the optional bottom isolation layer 800. The source/drains 82N are formed on the first semiconductor layer 110A (e.g., with or without the bottom isolation layer 800 therebetween) in the first device region 10A and on the second semiconductor layer 110D (e.g., with or without the bottom isolation layer 800 therebetween) in the third device region 10C, corresponding to act 2000 of FIG. 25. Formation of the source/drains 82N may be performed by a suitable epitaxial growth process, such as chemical vapor deposition (CVD), atomic layer deposition (ALD), vapor phase epitaxy (VPE), molecular beam epitaxy (MBE), or the like. In the first device region 10A, the source/drains 82N are in contact with the channels 22A, 22B, 22C. In the third device region 10C, the source/drains 82N are in contact with the channels 22B, 22C and are isolated from the channels 22A, for example, by the isolation structure 110E. The source/drains 82N in the third device region 10C are isolated from the substrate 110 and/or the fins 32 by the implantation region 110C. The source/drains 82N in the first device region 10A are in direct contact with the first semiconductor layer 110A or the bottom isolation layer 800 and are not isolated from the substrate 110 and/or fins 32 by an implantation region, due to the implantation regions 110C not being formed in the first device region 10A.

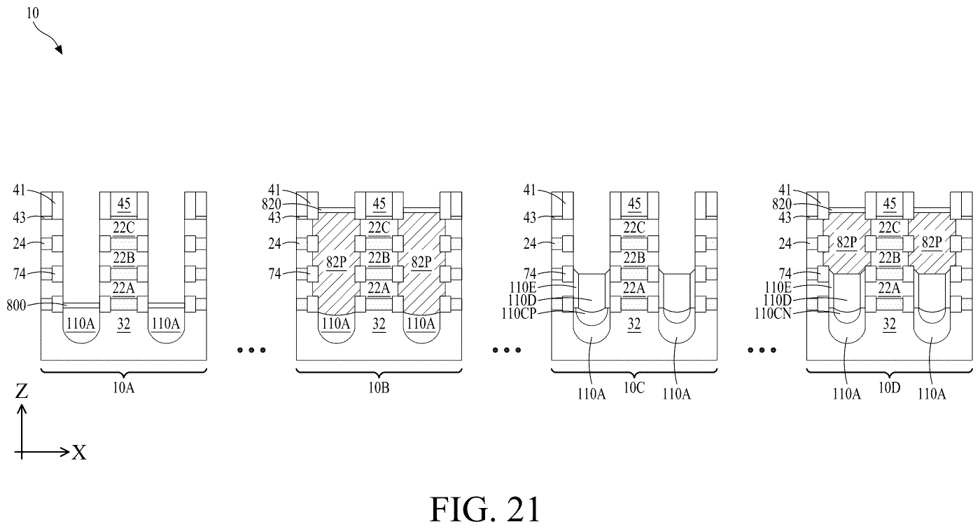

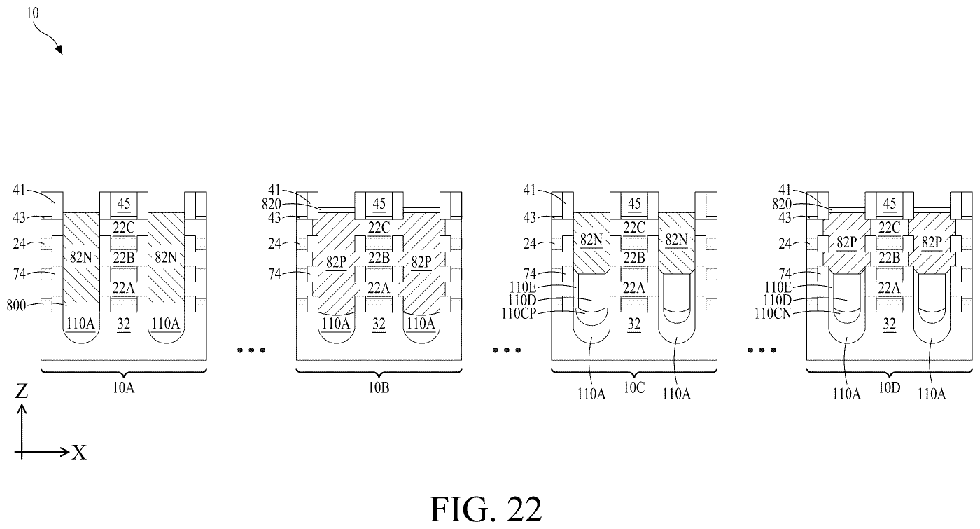

FIGS. 21 and 22 depict forming N-type source/drains 82N in accordance with embodiments in which the implantation regions 110CN, 110CP are formed having different dopant species as each other instead of the implantation regions 110C having the same dopant species as each other.

In FIG. 21, following formation of the source/drains 82P, the bottom isolation layer 800 and dielectric layer 820 are formed as described with reference to FIG. 19. However, in FIG. 21, the bottom isolation layer 800 is removed from or not formed on the second semiconductor layer 110D in the third device region 10C. For example, the bottom isolation layer 800 may be formed over the second semiconductor layer 110D, then may be removed by a suitable etching process. In another example, the third device region 10C may be masked during formation of the bottom isolation layer 800 so that the bottom isolation layer 800 is not formed on the second semiconductor layer 110D.

In the third device region 10C, due to presence of the implantation region 110CP having different dopant type (e.g., P-type) than the source/drain 82N to be formed (e.g., N-type), isolation between the source/drain 82N to be formed and the substrate 110 and/or fins 32 may be sufficiently high that the bottom isolation layer 800 may be omitted in the third device region 10C. Another reason for not forming the bottom isolation layer 800 in the third device region 10C may be differences in strain tuning selection between 3-sheet devices in the first device region 10A and 2-sheet devices in the third device region 10C. In some embodiments, the bottom isolation layer 800 may be formed in the third device region 10C on the second semiconductor layer 110D when the implantation region 110CP is present in the third device region 10C, which may increase isolation between the source/drain 82N to be formed and the substrate 110 and/or fins 32.

In FIG. 22, following formation of the bottom isolation layer 800, the N-type source/drains 82N are formed, which may be similar in most respects to the embodiments described with reference to FIG. 20 other than that the source/drain 82N formed in the third device region 10C in FIG. 22 may be formed in direct contact with the second semiconductor layer 110D and over the implantation region 110CP.

Following formation of the N-type source/drains 82N as depicted in FIG. 22, the operations described with reference to FIGS. 12A and 12B may be performed to form source/drain contacts 120 and replacement gates 200.

FIGS. 23A and 23B depict a device 10 having the isolation structures 110B, the isolation structures 110E, the second semiconductor layer 110D and the implantation regions 110C. For example, the operations described with reference to FIGS. 7A-8B may be performed to form the layer 110BL. Then, the operations described with reference to FIGS. 9A, 9B and FIG. 14 or 15 may be performed to form the first semiconductor layer 110A and the implantation regions 110C. Then, the second semiconductor layer 10D may be formed as described with reference to FIG. 16. Then, the layer 110BL may be patterned to form the isolation structures 110B, 110E similar to described with reference to FIG. 17. The isolation structures 110B, 110E may be a single, continuous structure due to being formed from the same layer 110BL. In such embodiments, the isolation structure including the isolation structures 110B, 110E may extend to depth below the implantation regions 110C, such that side surfaces of the implantation regions 110C are in direct contact with side surfaces of the isolation structure 110B and/or the isolation structure 110E. As depicted in FIG. 23B, the side surfaces of the isolation structure(s) 110B, 110E may be in direct contact with the first semiconductor layer 110A, the implantation region 110C, the second semiconductor layer 110D, the fin spacer 41F and the isolation region 36.

Embodiments may provide advantages. The source/drains 82N, 82P may be effectively isolated from the substrate 110 and/or fins 32 for both n-type and p-type FETs while maintaining an improved strain effect on the PFETs. The isolation structure(s) 110B, 110E are positioned between the substrate 110 and/or fin 32 and the undoped semiconductor layer 110A to isolate the source/drain 82N, 82P and the semiconductor layer 110A from the adjacent substrate 110, while keeping the surface of the undoped semiconductor layer 110A exposed for PFET source/drain epitaxial growth to improve strain behavior. Bulk leakage and well isolation leakage can be efficiently suppressed by the isolation structures 110B, 110E. The effective capacitance Ceff can be further reduced by including the bottom implantation region 110C, 110CN, 110CP having an anti-dopant therein.

In accordance with at least one embodiment, a device includes: a substrate having a semiconductor fin; a stack of semiconductor channels on the substrate and positioned over the fin; a gate structure wrapping around the semiconductor channels; a source/drain abutting the semiconductor channels; an inner spacer positioned between the stack of semiconductor channels and the fin; an undoped semiconductor layer vertically adjacent the source/drain and laterally adjacent the fin; and an isolation structure that laterally surrounds the undoped semiconductor layer, the isolation structure being between the source/drain and the inner spacer.

In accordance with at least one embodiment, a method includes: forming a stack of semiconductor nanostructure layers over a substrate; forming a stack of semiconductor nanostructures by forming a source/drain opening through the stack of semiconductor nanostructure layers; forming a dielectric layer on surfaces exposed by the source/drain opening; forming a first semiconductor layer on the dielectric layer in the source/drain opening; forming an isolation structure by removing portions of the dielectric layer exposed by the first semiconductor layer; and forming a source/drain on the first semiconductor layer and abutting the stack of semiconductor nanostructures.

In accordance with at least one embodiment, a method includes: forming a stack of nanostructures over a substrate by forming a source/drain opening; forming a first semiconductor layer in the source/drain opening; forming an isolating layer in the source/drain opening on the first semiconductor layer; forming an isolation layer by thinning the isolating layer, the forming an isolation layer exposing an upper surface of the first semiconductor layer; forming an implantation region including first dopants of a first type by directing the first dopants onto the upper surface of the first semiconductor layer; forming a second semiconductor layer on the implantation region; forming an isolation structure by removing portions of the isolation layer exposed by the second semiconductor layer; and forming a source/drain on the second semiconductor layer, the source/drain being of a second type different than the first type.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate having a semiconductor fin;
a stack of semiconductor channels on the substrate and positioned over the fin;
a gate structure wrapping around the semiconductor channels;
a source/drain abutting the semiconductor channels;
an inner spacer positioned between the stack of semiconductor channels and the fin;
an undoped semiconductor layer vertically adjacent the source/drain and laterally adjacent the fin; and
an isolation structure that laterally surrounds the undoped semiconductor layer on lateral sides of the undoped semiconductor layer, the isolation structure being between the undoped semiconductor layer and a side surface the fin.

2. The device of claim 1, wherein the isolation structure has thickness that is in a range of about 1 nanometer to about 3 nanometers.

3. The device of claim 1, wherein the isolation structure is in direct contact with the source/drain.

4. The device of claim 1, further comprising a bottom isolation layer, the isolation structure being separated from the source/drain by the bottom isolation layer.

5. The device of claim 1, further comprising an implantation region between the undoped semiconductor layer and the source/drain, a first type of dopant species in the implantation region being opposite a second type of the source/drain.

6. The device of claim 5, further comprising a second semiconductor layer between the implantation region and the source/drain.

7. The device of claim 6, further comprising a bottom isolation layer between the source/drain and the second semiconductor layer.

8. The device of claim 5, further comprising:
a second stack of semiconductor channels offset from the stack of semiconductor channels;
a second source/drain abutting the second stack of semiconductor channels; and
a second implantation region beneath the second source/drain, a third type of dopant species in the second implantation region being opposite the first type of dopant species in the implantation region.

9. The device of claim 8, further comprising a third semiconductor layer between the second implantation region and the second source/drain.

10. The device of claim 9, wherein the second source/drain is in direct contact with the third semiconductor layer and the source/drain is isolated from the second semiconductor layer by a bottom isolation layer.

11. A method, comprising:
forming a stack of semiconductor nanostructure layers over a substrate;
forming a stack of semiconductor nanostructures by forming a source/drain opening through the stack of semiconductor nanostructure layers;
forming a dielectric layer on surfaces exposed by the source/drain opening;
forming a first semiconductor layer on the dielectric layer in the source/drain opening;
forming an isolation structure by patterning the dielectric layer to leave vertical portions of the dielectric layer alongside surfaces of a fin adjacent the first semiconductor layer; and
forming a source/drain on the first semiconductor layer and abutting the stack of semiconductor nanostructures.

12. The method of claim 11, further comprising forming an exposed portion of the substrate by removing a horizontal portion of the dielectric layer, wherein the forming a semiconductor layer includes growing the semiconductor layer on the exposed portion.

13. The method of claim 11, wherein the forming a source/drain includes growing the source/drain directly on the first semiconductor layer.

14. The method of claim 11, further comprising forming a bottom insulator on the first semiconductor layer, wherein the forming a source/drain includes growing the source/drain from the stack of semiconductor nanostructures without substantially growing the source/drain from the first semiconductor layer.

15. The method of claim 11, further comprising:
forming a second stack of semiconductor nanostructures offset from the stack of semiconductor nanostructures by forming a second source/drain opening in the stack of nanostructure layers; and
during the forming a first semiconductor layer, forming a second semiconductor layer that has side surfaces in direct contact with a fin over which the second stack of semiconductor nanostructures is positioned.

16. A method, comprising:
forming a stack of nanostructures over a substrate by forming a source/drain opening;
forming a first semiconductor layer in the source/drain opening;
forming an isolating layer in the source/drain opening on the first semiconductor layer;
patterning the isolating layer to expose an upper surface of the first semiconductor layer while retaining isolating material alongside surfaces within the source/drain opening;
forming an implantation region including first dopants of a first type by directing the first dopants onto the upper surface of the first semiconductor layer;
forming a second semiconductor layer on the implantation region, wherein forming the second semiconductor layer includes forming the second semiconductor layer to a level above an upper surface of a bottommost one of the nanostructures to disable the bottommost nanostructure;
forming an isolation structure by removing portions of the isolation layer exposed by the second semiconductor layer; and
forming a source/drain on the second semiconductor layer, the source/drain being of a second type different than the first type.

17. The method of claim 16, wherein forming the second semiconductor layer includes forming the second semiconductor layer to a level above an upper surface of one of the nanostructures above the bottommost nanostructure to disable the bottommost nanostructure and nanostructure above the bottommost nanostructure.

18. The method of claim 16, wherein the forming a source/drain includes growing the source/drain directly from the second semiconductor layer.

19. The method of claim 16, further comprising:
forming a second stack of nanostructures by forming a second source/drain opening;
forming a second implantation region in the second source/drain opening, the second implantation region including the first dopants of the first type;
forming a third semiconductor layer on the second implantation region;
forming a bottom insulator on the third semiconductor layer; and
forming a second source/drain on the bottom insulator, the second source/drain being of the first type.

20. The method of claim 16, further comprising:
forming a second stack of nanostructures by forming a second source/drain opening;
forming a second implantation region in the second source/drain opening, the second implantation region including second dopants of the second type;
forming a third semiconductor layer on the second implantation region; and
forming a second source/drain directly from the third semiconductor layer, the second source/drain being of the first type.
